(19) United States
(12) Patent Application Publication
(10) Pub. No.: US 2023/0043635 A1
(43) Pub. Date: Feb. 9, 2023

(54) SEMICONDUCTOR DEVICE AND METHOD

(71) Applicant: Taiwan Semiconductor Manufacturing Co., Ltd., Hsinchu (TW)

(72) Inventors: Pei-Yu Chou, Hsinchu (TW); Chia-Ming Hsu, Hualien County (TW); Tze-Liang Lee, Hsinchu (TW)

(21) Appl. No.: 17/654,627

(22) Filed: Mar. 14, 2022

Related U.S. Application Data
(60) Provisional application No. 63/229,618, filed on Aug. 5, 2021.

(51) Int. Cl. H01L 21/768; H01L 23/522

(52) U.S. Cl. CPC H01L 21/76805; H01L 21/7685; H01L 23/5226; H01L 21/76865; H01L 23/53209

(57) ABSTRACT

A method includes forming a gate structure over a substrate; forming a source/drain region adjacent the gate structure; forming a first interlayer dielectric (ILD) over the source/drain region; forming a contact plug extending through the first ILD that electrically contacts the source/drain region; forming a silicide layer on the contact plug; forming a second ILD extending over the first ILD and the silicide layer; etching an opening extending through the second ILD and the silicide layer to expose the contact plug, wherein the silicide layer is used as an etch stop during the etching of the opening; and forming a conductive feature in the opening that electrically contacts the contact plug.

### PRIORITY CLAIM AND CROSS-REFERENCE

This application claims the benefit of U.S. Provisional Application No. 63/229,218 filed on Aug. 5, 2021, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a Fin Field-Effect Transistor (FinFET) in a three-dimensional view, in accordance with some embodiments.

FIGS. 2, 3, 4, 5, 6, and 7 are cross-sectional views of intermediate stages in the manufacturing of FinFET devices, in accordance with some embodiments.

FIGS. 8A, 8B, 9A, 9B, 10A, 10B, 10C, 10D, 11A, 11B, 12A, 12B, 13A, 13B, 14A, 14B, and 14C are cross-sectional views of intermediate stages in the manufacturing of FinFET devices, in accordance with some embodiments.

FIGS. 15A, 15B, 16A, 16B, 17A, 17B, 18A, and 18B are cross-sectional views of intermediate stages in the manufacturing of conductive features of FinFET devices, in accordance with some embodiments.

FIGS. 19A, 19B, 20A, 20B, 21A, 21B, 22A, 22B, 23A, 23B, 24A, 24B, 25A, and 25B are cross-sectional views of intermediate stages in the manufacturing of FinFET devices, in accordance with some embodiments.

FIGS. 26A and 26B are cross-sectional views of intermediate stages in the manufacturing of Nanostructure Field-Effect Transistor (NFET) devices, in accordance with some embodiments.

FIGS. 27A, 27B, 27C, 28A, 28B, and 28C are cross-sectional views of intermediate stages in the manufacturing of conductive features of FinFET devices, in accordance with some embodiments.

FIGS. 29A, 29B, and 29C are cross-sectional views of intermediate stages in the manufacturing of FinFET devices, in accordance with some embodiments.

FIGS. 30A, 30B, 31A, and 31B are cross-sectional views of intermediate stages in the manufacturing of FinFET devices, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to a specific context, namely, a contact plug structure of a semiconductor device and a method of forming the same. Various embodiments presented herein are discussed in the context of a Fin Field Effect Transistor (FinFET) device formed using a gate-last process. In other embodiments, a gate-first process may be used. Various embodiments may be applied, however, to dies comprising other types of transistors such as planar FETs, nanostructure (e.g., nanosheet, nanowire, gate-all-around (GAA), or the like) field effect transistors (NFETs/NSFETs), or the like in lieu of or in combination with the FinFETs. In some embodiments, silicide layers are formed on the contact plugs of a semiconductor device. The silicide layers may be used as an etch stop layer during subsequent processing steps, such as those for forming conductive features on the contact plugs. By forming a silicide as an etch stop layer, the overall number of manufacturing steps may be reduced, which can reduce manufacturing costs. The silicide may be formed using relatively low temperature processes, which can reduce thermal effects during device manufacturing. The use of the silicide layers as etch stops can also reduce the overall thickness of the device.

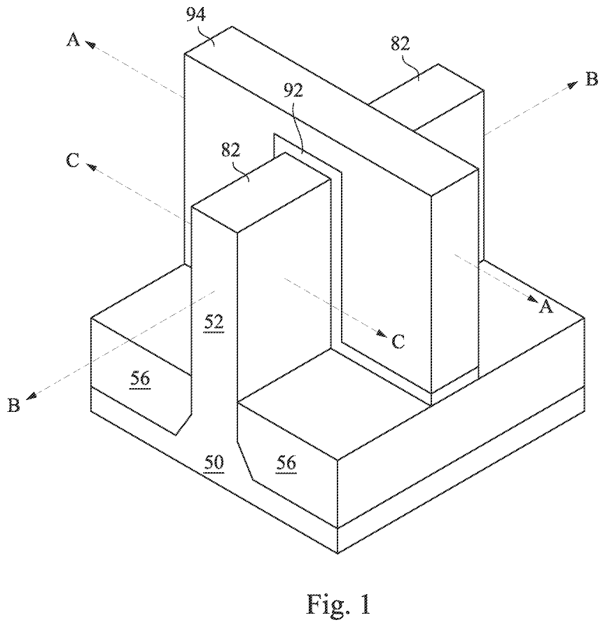

FIG. 1 illustrates an example of a FinFET in a three-dimensional view, in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and the gate electrode 94. FIG. 1 further illustrates reference cross-sections that are used in later figures. Cross-section A-A is along a longitudinal axis of the gate electrode 94 and in a direction, for example, perpendicular to the direction of current flow between the source/drain regions 82 of the FinFET. Cross-section B-B is perpendicular to cross-section A-A and is along a longitudinal axis of the fin 52 and in a direction of, for example, a current flow between the source/drain regions 82 of the FinFET. Cross-section C-C is parallel to cross-section A-A and extends through a source/drain region of the FinFET. Subsequent figures refer to these reference cross-sections for clarity.

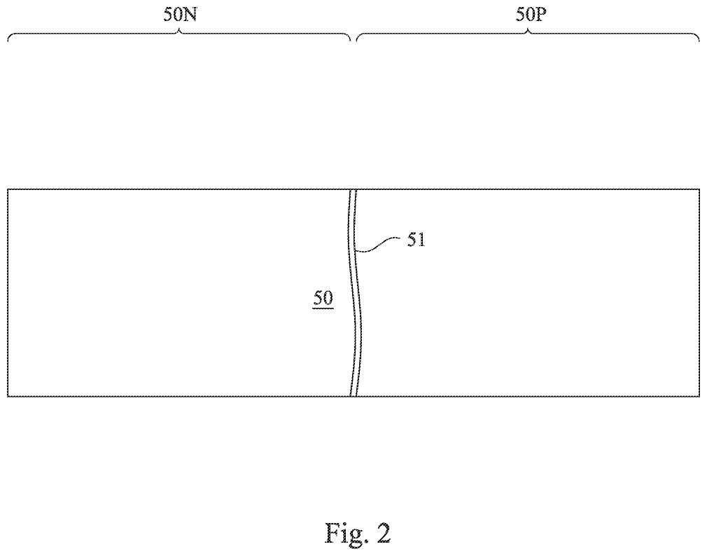

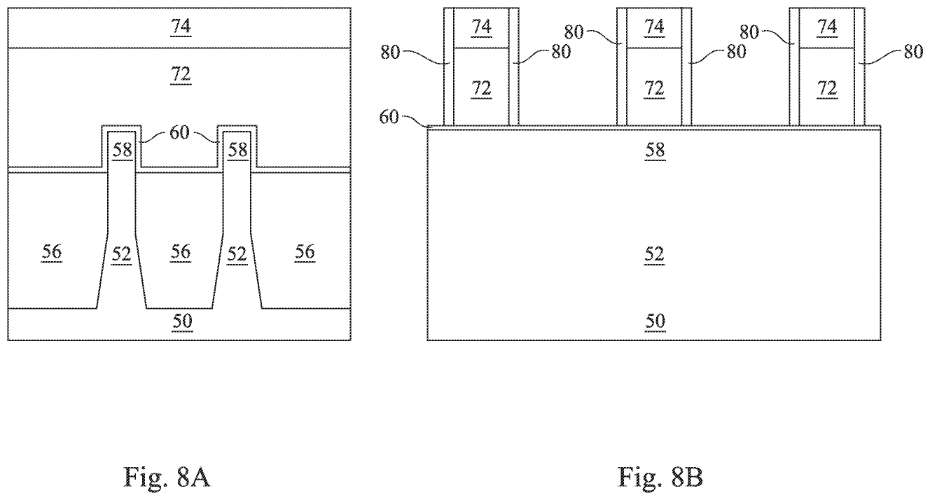

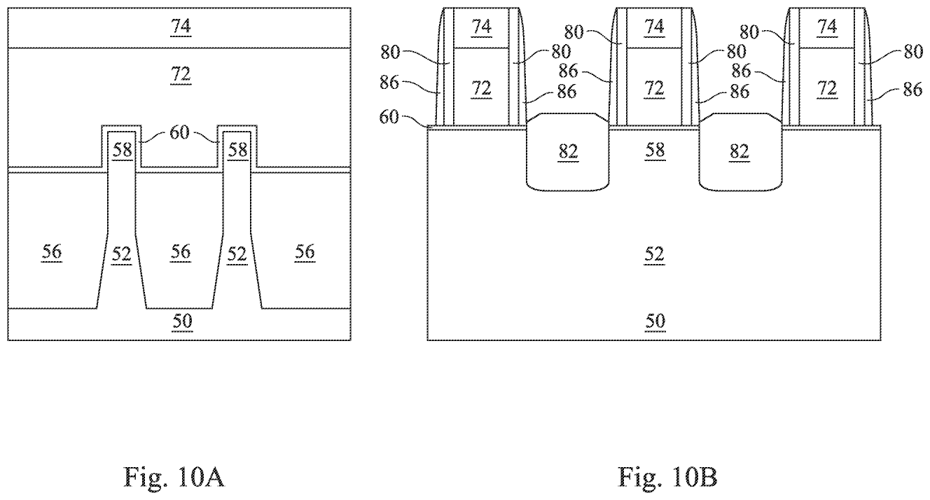

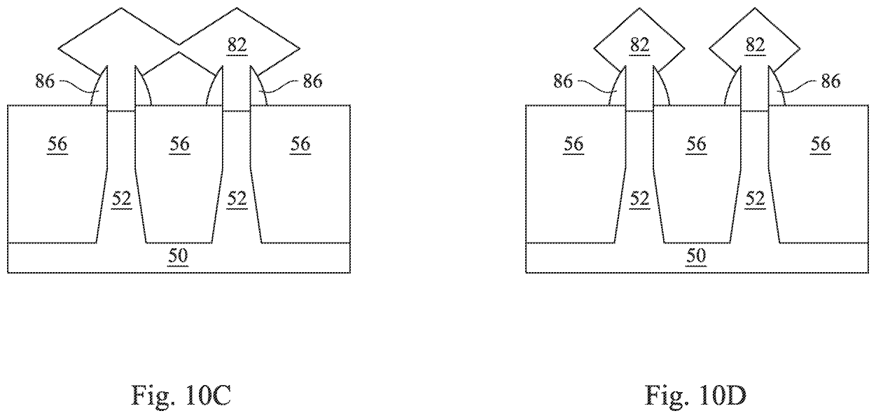

FIGS. 2 through 25B are cross-sectional views of intermediate stages in the manufacturing of FinFET devices, in accordance with some embodiments. FIGS. 2 through 7 illustrate reference cross-section A-A illustrated in FIG. 1, except for multiple fins/FinFETs. FIGS. 8A, 9A, 10A, 11A, 12A, 13A, 14A, 15A, 16A, 17A, 18A, 19A, 20A, 21A, 22A, 23A, 24A, and 25A are illustrated along reference cross-section A-A illustrated in FIG. 1, and FIGS. 8B, 9B, 10B, 11B, 12B, 13B, 14B, 14C, 15B, 16B, 17B, 18B, 19B, 20B, 21B, 22B, 23B, 24B, and 25B are illustrated along a similar cross-section B-B illustrated in FIG. 1, except for multiple fins/FinFETs. FIGS. 10C and 10D are illustrated along reference cross-section C-C illustrated in FIG. 1, except for multiple fins/FinFETs.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; the like; or combinations thereof.

The substrate 50 has an n-type region 50N and a p-type region 50P. The n-type region 50N can be for forming n-type devices, such as NMOS transistors, e.g., n-type FinFETs. The p-type region 50P can be for forming p-type devices, such as PMOS transistors, e.g., p-type FinFETs. The n-type region 50N may be physically separated from the p-type region 50P (as illustrated by divider 51), and any number of device features (e.g., other active devices, doped regions, isolation structures, etc.) may be disposed between the n-type region 50N and the p-type region 50P.

In FIG. 3, fins 52 are formed in the substrate 50, in accordance with some embodiments. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

The fins 52 may be patterned by any suitable method. For example, the fins 52 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as a mask to form the fins 52. In some embodiments, the mask (or other layer) may remain on the fins 52.

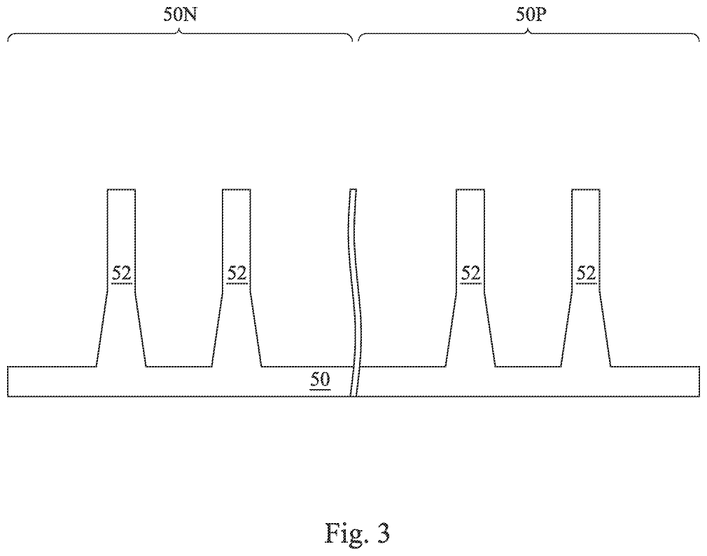

In FIG. 4, an insulation material 54 is formed over the substrate 50 and between neighboring fins 52, in accordance with some embodiments. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments a liner (not shown) may first be formed along surfaces of the substrate 50 and the fins 52. Thereafter, a fill material such as those discussed above may be formed over the liner.

In FIG. 5, a removal process is applied to the insulation material 54 to remove excess insulation material 54 over the fins 52. In some embodiments, a planarization process such as a chemical mechanical polish (CMP), an etch-back process, a combination thereof, or the like may be utilized. The planarization process exposes the fins 52 such that top surfaces of the fins 52 and the insulation material 54 are substantially coplanar or level (e.g., within process variations of the planarization process) after the planarization process is completed. In embodiments in which a mask remains on the fins 52, the planarization process may expose the mask or remove the mask such that top surfaces of the mask or the fins 52, respectively, and the insulation material 54 are level after the planarization process is completed.

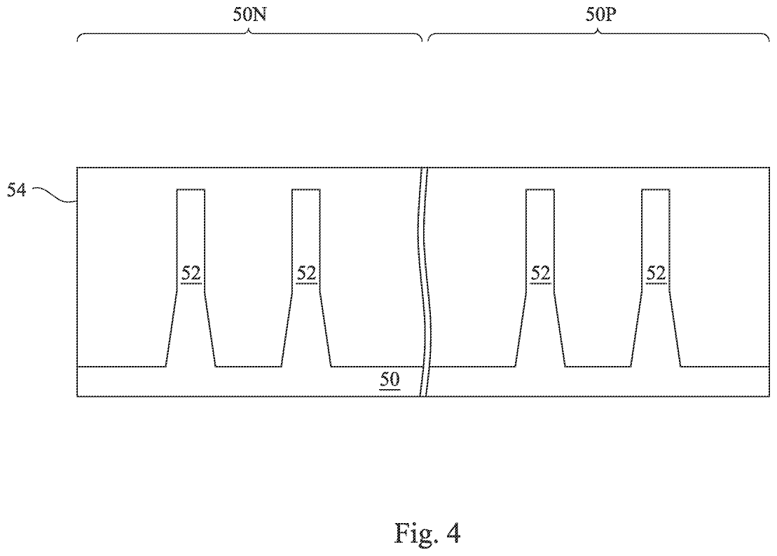

In FIG. 6, the insulation material 54 is recessed to form Shallow Trench Isolation (STI) regions 56, in accordance with some embodiments. The insulation material 54 is recessed such that upper portions of fins 52 in the n-type region 50N and in the p-type region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, an oxide removal process using dilute hydrofluoric acid (dHF) may be used, though other processes are possible.

The process described with respect to FIGS. 2 through 6 is just one example of how the fins 52 may be formed. In some embodiments, the fins may be formed by an epitaxial growth process. For example, a dielectric layer can be formed over a top surface of the substrate 50, and trenches can be etched through the dielectric layer to expose the underlying substrate 50. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins 52. For example, the fins 52 in FIG. 5 can be recessed, and a material different from the fins 52 may be epitaxially grown over the recessed fins 52. In such embodiments, the fins 52 comprise the recessed material as well as the epitaxially grown material disposed over the recessed material. In an even further embodiment, a dielectric layer can be formed over a top surface of the substrate 50, and trenches can be etched through the dielectric layer. Heteroepitaxial structures can then be epitaxially grown in the trenches using a material different from the substrate 50, and the dielectric layer can be recessed such that the heteroepitaxial structures protrude from the dielectric layer to form the fins 52. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in n-type region 50N (e.g., an NMOS region) different from the material in p-type region 50P (e.g., a PMOS region). In various embodiments, upper portions of the fins 52 may be formed from silicon germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further in FIG. 6, appropriate wells (not shown) may be formed in the fins 52 and/or the substrate 50. In some embodiments, a P well may be formed in the n-type region 50N, and an N well may be formed in the p-type region 50P. In some embodiments, a P well or an N well are formed in both the n-type region 50N and the p-type region 50P. In the embodiments with different well types, the different implant steps for the n-type region 50N and the p-type region 50P may be achieved using a photoresist and/or other masks (not shown). For example, a photoresist may be formed over the fins 52 and the STI regions 56 in the n-type region 50N. The photoresist is patterned to expose the p-type region 50P of the substrate 50. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration of equal to or less than 10¹⁸ cm⁻³, such as in the range of about 10¹⁶ cm⁻³ to about 10¹⁸ cm⁻³. After the implant, the photoresist is removed, such as by an acceptable ashing process.

Following the implanting of the p-type region 50P, a photoresist is formed over the fins 52 and the STI regions 56 in the p-type region 50P. The photoresist is patterned to expose the n-type region 50N of the substrate 50. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration of equal to or less than 10¹⁸ cm⁻³, such as in the range of about 10¹⁶ cm⁻³ to about 10¹⁸ cm⁻³. After the implant, the photoresist may be removed, such as by an acceptable ashing process.

After the implanting of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

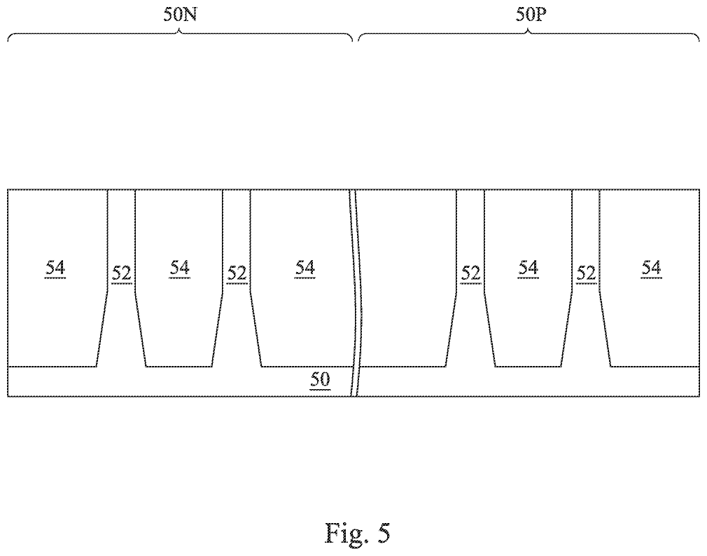

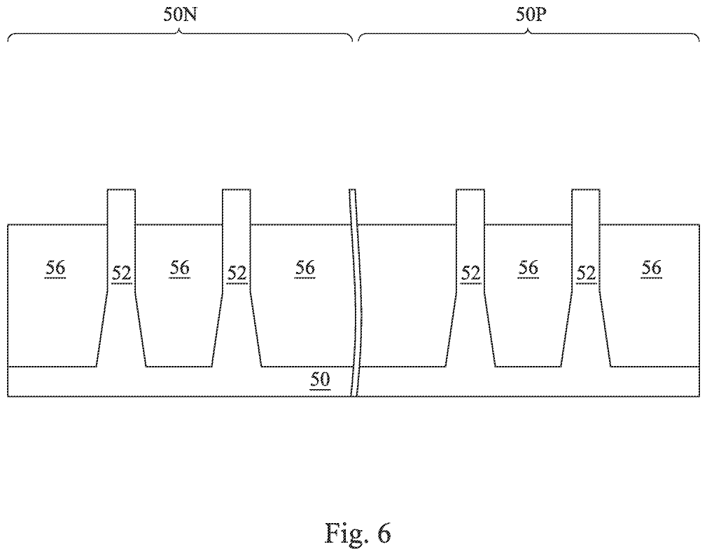

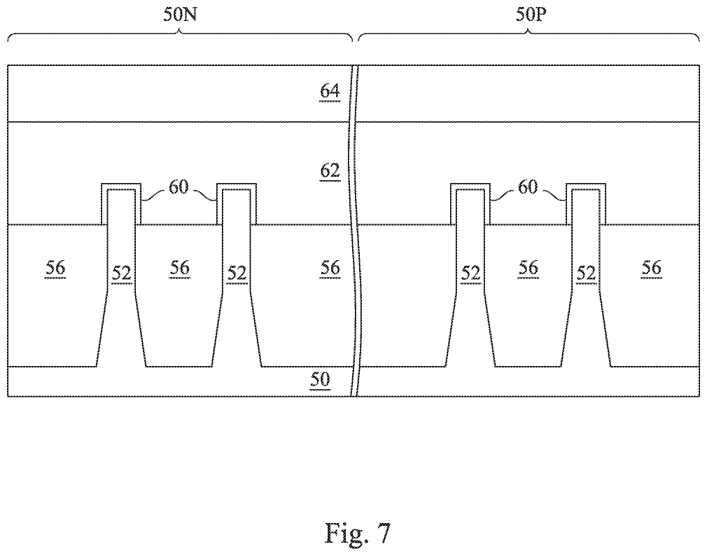

In FIG. 7, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized using, for example, a CMP process. The mask layer 64 may be deposited over the dummy gate layer 62. The dummy gate layer 62 may be a conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques known and used in the art for depositing conductive materials. The dummy gate layer 62 may be made of other materials that have a high etching selectivity than materials of the STI regions 56. The mask layer 64 may include, for example, one or more layers of silicon oxide, SiN, SiON, a combination thereof, or the like. In some embodiments, the mask layer 64 may comprise a layer of silicon nitride and a layer of silicon oxide over the layer of silicon nitride. In some embodiments, a single dummy gate layer 62 and a single mask layer 64 are formed across the region 50N and the region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending between the dummy gate layer 62 and the STI regions 56.

FIGS. 8A through 25B illustrate various additional steps in the manufacturing of embodiment devices. FIGS. 8A through 25B illustrate features in either of the n-type region 50N and the p-type region 50P. For example, the structures illustrated in FIGS. 8A through 25B may be applicable to both the n-type region 50N and the p-type region 50P. Differences (if any) in the structures of the n-type region 50N and the p-type region 50P are described in the text accompanying each figure.

In FIGS. 8A and 8B, the mask layer 64 (see FIG. 7) may be patterned using acceptable photolithography and etching techniques to form masks 74. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective epitaxial fins 52.

Further in FIGS. 8A and 8B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, similar to the implants discussed above in FIG. 6, a mask, such as a photoresist, may be formed over the n-type region 50N, while exposing the p-type region 50P, and appropriate type (e.g., p-type) impurities may be implanted into the exposed fins 52 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 52 in the n-type region 50N. The mask may then be removed. The n-type impurities may be the any of the n-type impurities previously discussed, and the p-type impurities may be the any of the p-type impurities previously discussed. In some embodiments, the lightly doped source/drain regions may have a concentration of impurities in the range of about 10¹⁵ cm⁻³ to about 10¹⁹ cm⁻³. An anneal may be used to repair implant damage and/or to activate the implanted impurities.

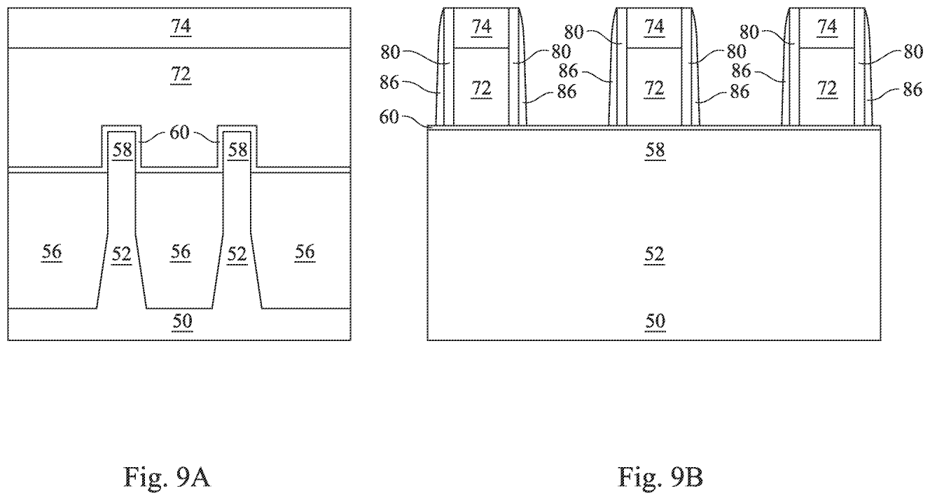

In FIGS. 9A and 9B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may be silicon oxide, silicon nitride, silicon oxynitride, silicon carbonitride, a combination thereof, or the like. In some embodiments, the gate spacers 86 comprise multiple layers, which may be layers of different materials.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers, spacers may be formed and removed, and/or the like). Furthermore, the n-type and p-type devices may be formed using a different structures and steps. For example, LDD regions for n-type devices may be formed prior to forming the gate seal spacers 80 while the LDD regions for p-type devices may be formed after forming the gate seal spacers 80.

In FIGS. 10A and 10B epitaxial source/drain regions 82 are formed in the fins 52. The epitaxial source/drain regions 82 are formed in the fins 52 such that each dummy gate 72 is disposed between respective neighboring pairs of the epitaxial source/drain regions 82. In some embodiments the epitaxial source/drain regions 82 may extend into, and may also penetrate through, the fins 52. In some embodiments, the gate spacers 86 are used to separate the epitaxial source/drain regions 82 from the dummy gates 72 by an appropriate lateral distance so that the epitaxial source/drain regions 82 do not short out subsequently formed gates of the resulting FinFETs. A material of the epitaxial source/drain regions 82 may be selected to exert stress in the respective channel regions 58, thereby improving performance.

The epitaxial source/drain regions 82 in the n-type region 50N may be formed by masking the p-type region 50P and etching source/drain regions of the fins 52 in the n-type region 50N to form recesses in the fins 52. Then, the epitaxial source/drain regions 82 in the n-type region 50N are epitaxially grown in the recesses. The epitaxial source/drain regions 82 may include any acceptable material, such as appropriate for n-type FinFETs. For example, if the fin 52 is silicon, the epitaxial source/drain regions 82 in the n-type region 50N may include materials exerting a tensile strain in the channel region 58, such as silicon, silicon carbide, phosphorous doped silicon carbide, silicon phosphide, or the like. The epitaxial source/drain regions 82 in the n-type region 50N may have surfaces raised from respective surfaces of the fins 52 and may have facets.

The epitaxial source/drain regions 82 in the p-type region 50P may be formed by masking the n-type region 50N and etching source/drain regions of the fins 52 in the p-type region 50P to form recesses in the fins 52. Then, the epitaxial source/drain regions 82 in the p-type region 50P are epitaxially grown in the recesses. The epitaxial source/drain regions 82 may include any acceptable material, such as appropriate for p-type FinFETs. For example, if the fin 52 is silicon, the epitaxial source/drain regions 82 in the p-type region 50P may comprise materials exerting a compressive strain in the channel region 58, such as silicon-germanium, boron doped silicon-germanium, germanium, germanium tin, or the like. The epitaxial source/drain regions 82 in the p-type region 50P may have surfaces raised from respective surfaces of the fins 52 and may have facets.

The epitaxial source/drain regions 82 and/or the fins 52 may be implanted with dopants to form source/drain regions, similar to the process previously discussed for forming lightly-doped source/drain regions, followed by an anneal. The source/drain regions may have an impurity concentration in the range of about 10¹⁹ cm⁻³ to about 10²¹ cm⁻³. The n-type and/or p-type impurities for source/drain regions may be any of the impurities previously discussed. In some embodiments, the epitaxial source/drain regions 82 may be in situ doped during growth.

As a result of the epitaxy processes used to form the epitaxial source/drain regions 82 in the n-type region 50N and the p-type region 50P, upper surfaces of the epitaxial source/drain regions have facets which expand laterally outward beyond sidewalls of the fins 52. In some embodiments, these facets cause adjacent source/drain regions 82 of a same FinFET to merge as illustrated by FIG. 10C. In other embodiments, adjacent epitaxial source/drain regions 82 remain separated after the epitaxy process is completed as illustrated by FIG. 10D. In the embodiments illustrated in FIGS. 10C and 10D, gate spacers 86 are formed covering a portion of the sidewalls of the fins 52 that extend above the STI regions 56, thereby blocking the epitaxial growth. In some other embodiments, the spacer etch used to form the gate spacers 86 may be adjusted to remove the spacer material to allow the epitaxially grown region to extend to the surface of the STI region 56.

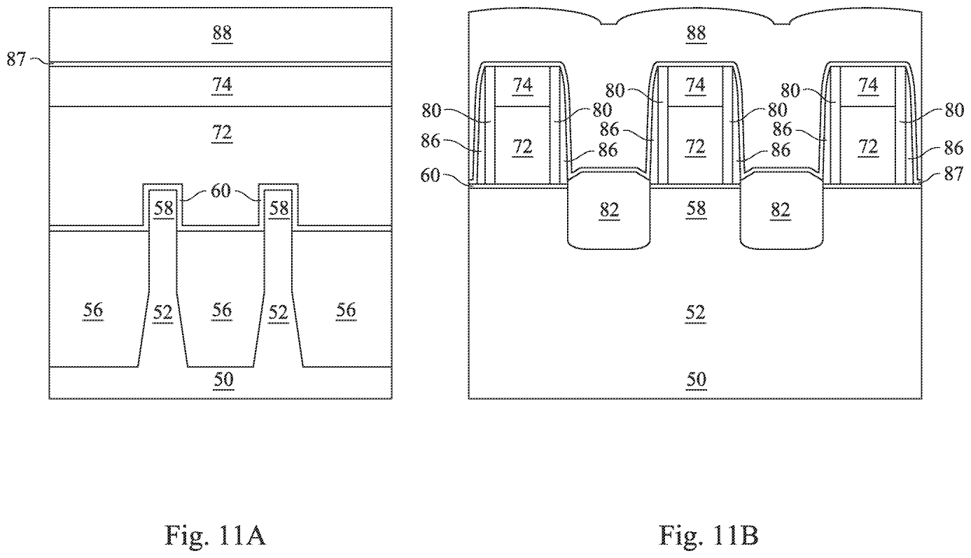

In FIGS. 11A and 11B, a first interlayer dielectric (ILD) 88 is deposited over the structure illustrated in FIGS. 10A and 10B. The first ILD 88 may be formed of a dielectric material, and may be deposited by any suitable method, such as CVD, plasma-enhanced CVD (PECVD), or FCVD. Dielectric materials may include pho spho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 87 is disposed between the first ILD 88 and the epitaxial source/drain regions 82, the masks 74, and the gate spacers 86. The CESL 87 may comprise a dielectric material, such as, silicon nitride, silicon oxide, silicon oxynitride, or the like, having a lower etch rate than the material of the overlying first ILD 88.

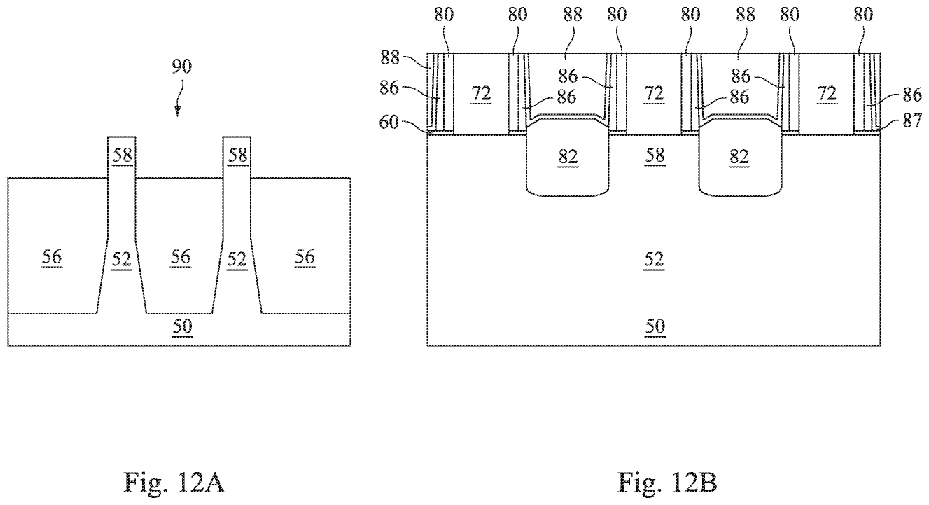

In FIGS. 12A and 12B, a planarization process, such as a CMP, may be performed to level the top surface of the first ILD 88 with the top surfaces of the dummy gates 72 or the masks 74. The planarization process may also remove the masks 74 on the dummy gates 72, and portions of the gate seal spacers 80 and the gate spacers 86 along sidewalls of the masks 74. After the planarization process, top surfaces of the dummy gates 72, the gate seal spacers 80, the gate spacers 86, and the first ILD 88 are level. Accordingly, the top surfaces of the dummy gates 72 are exposed through the first ILD 88. In some embodiments, the masks 74 may remain, in which case the planarization process levels the top surface of the first ILD 88 with the top surface of the masks 74.

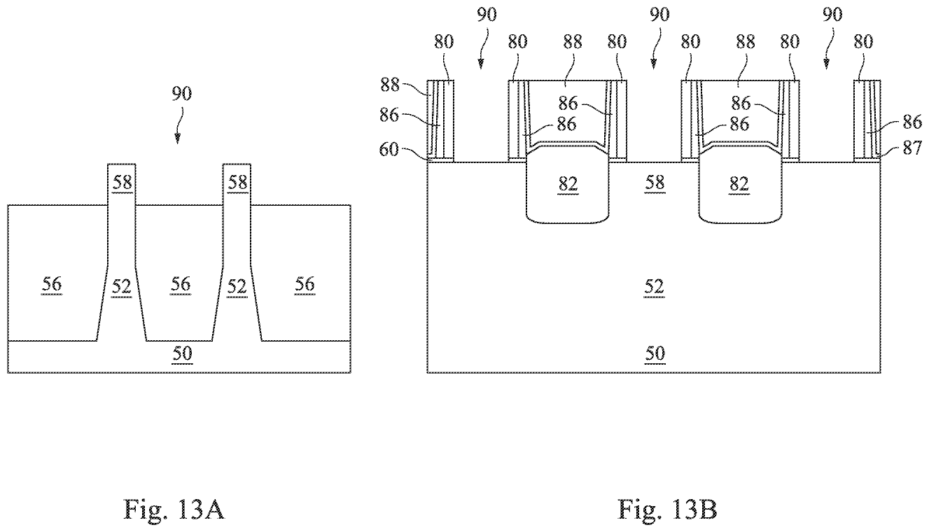

In FIGS. 13A and 13B, the dummy gates 72, and the masks 74 if present, are removed in an etching step(s), so that recesses 90 are formed. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process. For example, the etching process may include a dry etch process using reaction gas(es) that selectively etch the dummy gates 72 with little or no etching of the first ILD 88 or the gate spacers 86. Each recess 90 exposes and/or overlies a channel region 58 of a respective fin 52. Each channel region 58 is disposed between neighboring pairs of the epitaxial source/drain regions 82. During the removal, the dummy dielectric layer 60 may be used as an etch stop layer when the dummy gates 72 are etched. The dummy dielectric layer 60 may then be optionally removed after the removal of the dummy gates 72.

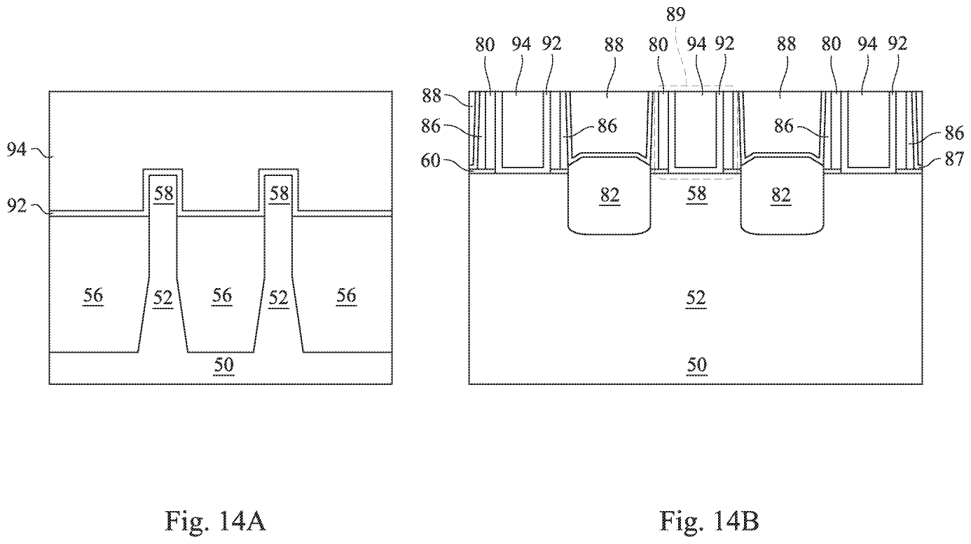

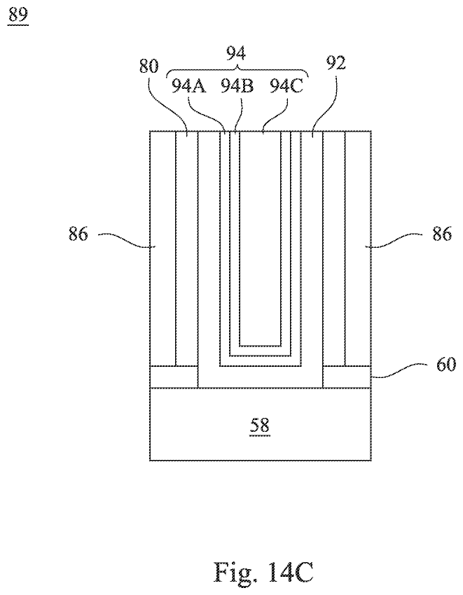

In FIGS. 14A and 14B, gate dielectric layers 92 and gate electrodes 94 are formed for replacement gates. FIG. 14C illustrates a detailed view of region 89 of FIG. 14B. Gate dielectric layers 92 one or more layers deposited in the recesses 90, such as on the top surfaces and the sidewalls of the fins 52 and on sidewalls of the gate seal spacers 80/gate spacers 86. The gate dielectric layers 92 may also be formed on the top surface of the first ILD 88. In some embodiments, the gate dielectric layers 92 comprise one or more dielectric layers, such as one or more layers of silicon oxide, silicon nitride, metal oxide, metal silicate, or the like. For example, in some embodiments, the gate dielectric layers 92 include an interfacial layer of silicon oxide formed by thermal or chemical oxidation and an overlying high-k dielectric material, such as a metal oxide or a silicate of hafnium, aluminum, zirconium, lanthanum, manganese, barium, titanium, lead, and combinations thereof. The gate dielectric layers 92 may include a dielectric layer having a k-value greater than about 7.0. The formation methods of the gate dielectric layers 92 may include Molecular-Beam Deposition (MBD), ALD, PECVD, and the like. In embodiments where portions of the dummy dielectric layer 60 remains in the recesses 90, the gate dielectric layers 92 include a material of the dummy dielectric layer 60 (e.g., silicon oxide or the like).

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode 94 is illustrated in FIG. 14B, the gate electrode 94 may comprise any number of liner layers 94A, any number of work function tuning layers 94B, and a fill material 94C as illustrated by FIG. 14C. After the filling of the recesses 90, a planarization process, such as a CMP, may be performed to remove the excess portions of the gate dielectric layers 92 and the material of the gate electrodes 94, which excess portions are over the top surface of the first ILD 88. The remaining portions of material of the gate electrodes 94 and the gate dielectric layers 92 thus form replacement gates of the resulting FinFETs. The gate electrodes 94 and the gate dielectric layers 92 may be collectively referred to as a “replacement gate,” a “gate structure,” or a “gate stack.” The gate and the gate stacks may extend along sidewalls of a channel region 58 of the fins 52.

The formation of the gate dielectric layers 92 in the n-type region 50N and the p-type region 50P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

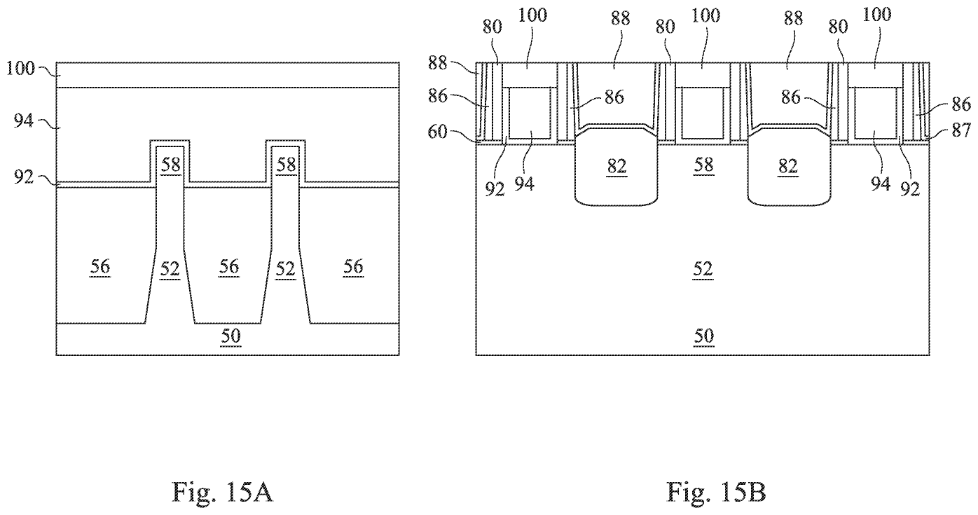

In FIGS. 15A and 15B, the gate stacks (e.g., the gate dielectric layers 92 and the gate electrodes 94) are recessed and dielectric layers 100 are formed over the gate stacks, in accordance with some embodiments. The dielectric layers 100 may be formed, for example, by recessing the gate stacks and depositing the dielectric material of the dielectric layers 100 on the recessed gate stacks. In some embodiments, the gate stacks are recessed below the top surface of the first ILD 88. The gate stacks may be recessed using one or more etch processes, which may include one or more wet etch processes, dry etch processes, or a combination thereof. The one or more etch processes may comprise anisotropic etch processes.

The dielectric layers 100 are then formed on the recessed gate stacks and over the first ILD 88. In some embodiments, the dielectric layers 100 comprise silicon oxide, silicon nitride, silicon oxynitride, silicon carbide, silicon carbonitride, a metal oxide, another type of oxide, another type of nitride, a combination thereof, or the like, and may be formed using ALD, CVD, PVD, a combination thereof, or the like. The dielectric layers 100 may be formed in a self-aligned manner, and sidewalls of a dielectric layer 100 may be aligned with respective sidewalls of the gate seal spacers 80 or the gate spacers 86. A planarization process, such as CMP process, may be performed to remove excess material of the dielectric layers 100 (e.g., from over the first ILD 88). In some cases, surfaces of the dielectric layers 100 and surfaces of the first ILD 88 may be approximately level. In some embodiments, the dielectric layers 100 may be formed having a thickness in the range of about 5 nm to about 50 nm.

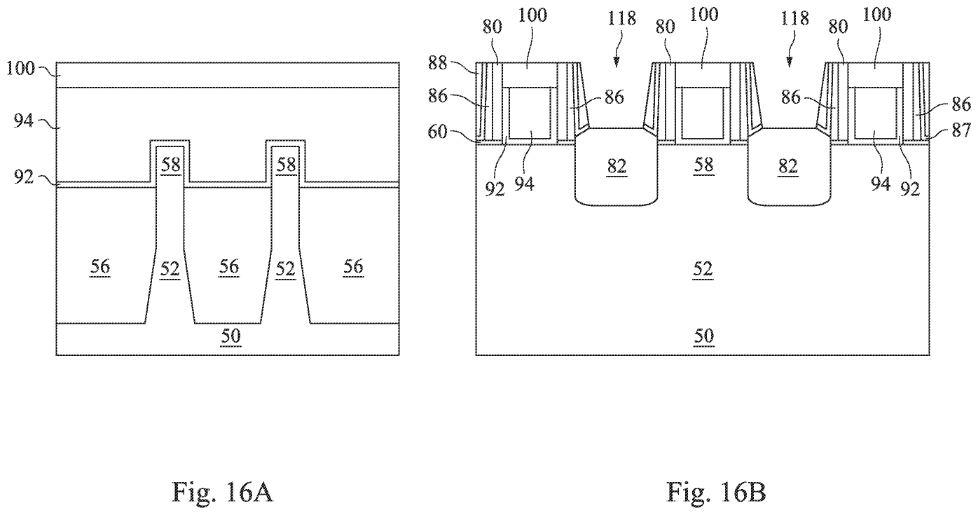

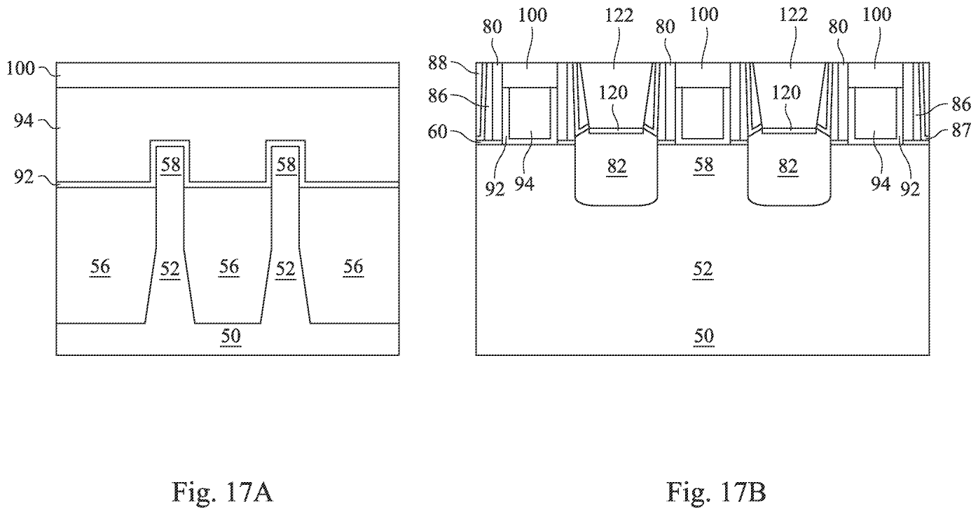

FIGS. 16A through 18B illustrate the formation of conductive features 122 (see FIG. 17B), in accordance with some embodiments. The conductive features 122 provide electrical connections to respective epitaxial source/drain regions 82 and in some cases may be considered “source/drain contact plugs” or the like.

FIGS. 16A and 16B illustrate a patterning process of the first ILD 88 and the CESL 87 to form openings 118, in accordance with some embodiments. The openings 118 may expose surfaces of the epitaxial source/drain regions 82. The patterning may be performed using acceptable photolithography and etching techniques. For example, a photoresist may be formed over the first ILD 88 and the dielectric layers 100 and patterned. The photoresist can be formed by using, for example, a spin-on technique and can be patterned using acceptable photolithography techniques. One or more suitable etch processes may be performed using the patterned photoresist as an etch mask, forming the openings 118. The one or more etch processes may include wet and/or dry etch processes. One or more of the etch processes may be anisotropic. FIGS. 16A-16B show the openings 118 as having sloped sidewalls, but the openings 118 may have substantially vertical sidewalls, curved sidewalls, or another sidewall profile than shown.

In FIGS. 17A and 17B, silicide layers 120 and conductive features 122 are formed in the openings 118, in accordance with some embodiments. The silicide layers 120 may be formed, for example, by depositing a metallic material in the openings 118. The metallic material may comprise Ti, Co, Ni, NiCo, Pt, NiPt, Ir, Ptlr, Er, Yb, Pd, Rh, Nb, a combination thereof, or the like, and may be formed using ALD, CVD, PVD, sputtering, a combination thereof, or the like. Subsequently, an annealing process is performed to form the silicide layers 120. In some embodiments in which the epitaxial source/drain regions 82 comprise silicon, the annealing process may cause the metallic material to react with silicon to form a silicide of the metallic material at interfaces between the metallic material and the epitaxial source/drain regions 82. After forming the silicide layers 120, unreacted portions of the metallic material may be removed using a suitable removal process, such as a suitable etch process, for example.

After forming the silicide layers 120, conductive features 122 are formed in the openings 118. The conductive features 122 provide electrical connections to respective epitaxial source/drain regions 82. In some embodiments, the conductive features 122 are formed by forming a liner (not shown), such as a barrier layer, an adhesion layer, or the like, and a conductive fill material are in the openings 118. For example, a barrier layer may first be formed in the openings 118. The barrier layer may extend along a bottom and sidewalls of the openings 118. The barrier layer may comprise titanium, titanium nitride, tantalum, tantalum nitride, a combination thereof, a multilayer thereof, or the like, and may be formed by ALD, CVD, PVD, sputtering, a combination thereof, or the like. Subsequently, an adhesion layer (not individually shown) may be formed over the barrier layer within the openings 118. The adhesion layer may comprise cobalt, ruthenium, an alloy thereof, a combination thereof, a multilayer thereof, or the like, and may be formed by ALD, CVD, PVD, sputtering, a combination thereof, or the like. The barrier layer and/or the adhesion layer may be omitted in other embodiments.

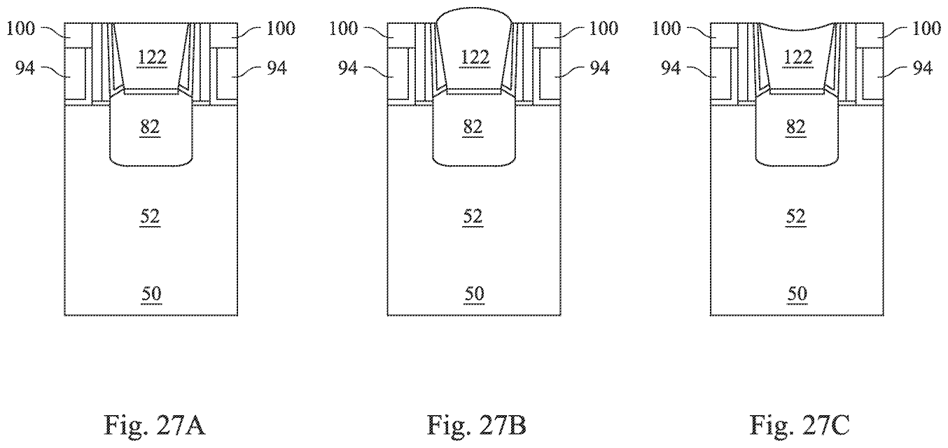

A conductive fill material is then formed in the openings 118 to form the conductive features 122. The conductive fill material may comprise copper, aluminum, tungsten, ruthenium, cobalt, combinations thereof, alloys thereof, multilayers thereof, or the like, and may be formed using, for example, by plating, ALD, CVD, PVD, or other suitable methods. For example, in some embodiments, the conductive fill material may be formed by first forming a seed layer (not individually shown) over the adhesion layer within the openings 118. The seed layer may comprise copper, titanium, nickel, gold, manganese, a combination thereof, a multilayer thereof, or the like, and may be formed by ALD, CVD, PVD, sputtering, a combination thereof, or the like. The conductive fill material may then be formed over the seed layer within the openings 118. Other techniques for forming the conductive fill material are possible. The conductive features 122 may have top surfaces that are concave, convex, or flat, or may have top surfaces that are above or below the top surface of the first ILD 88. Some conductive features 122 having different top surfaces are described below for FIGS. 27A-27C.

In some embodiments, the conductive fill material overfills the openings 118. After forming the conductive fill material, a planarization process may be performed to remove portions of the conductive fill material overfilling the openings 118. If present, portions of the barrier layer, the adhesion layer, and/or the seed layer may also be removed. Remaining portions of the barrier layer, the adhesion layer, the seed layer, and the conductive fill material form the conductive features 122 in the openings 118. The planarization process may comprise a CMP process, an etch back process, a grinding process, combinations thereof, or the like. After performing the planarization process, surfaces of the conductive features 122 and surfaces of the dielectric layers 100 may be substantially level. In other embodiments, a planarization process is not performed. In some embodiments, an optional anneal process is performed after the planarization process to recrystallize the conductive features 122, to enlarge the grain structure of the conductive features 122, to reduce micro-voids in the conductive features 122, and/or to reduce impurities in the conductive features 122.

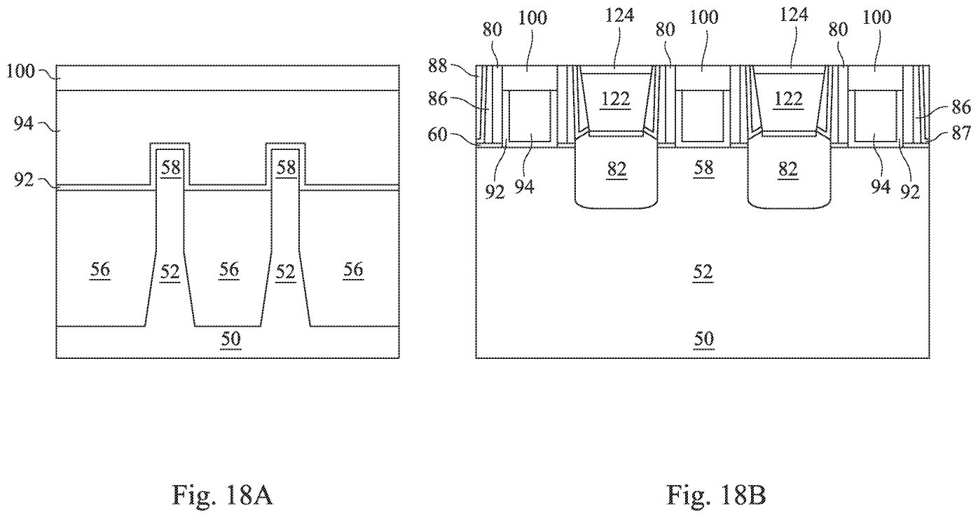

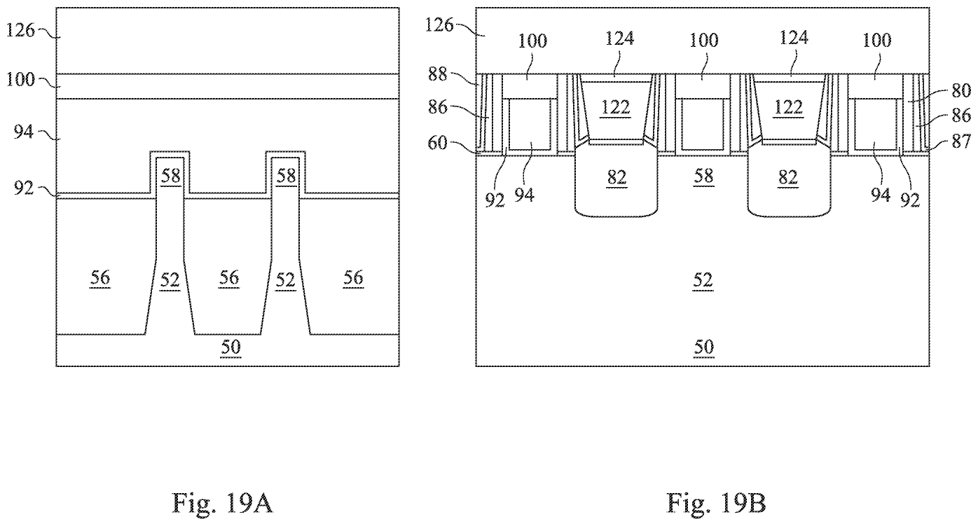

In FIGS. 18A and 18B, silicide layers 124 are formed on the conductive features 122, in accordance with some embodiments. In some embodiments, the silicide layers 124 may be used as etch stop layers during subsequent processing, described in greater detail below. For example, the silicide layers 124 may have a smaller etch rate than overlying layers such as the second ILD 126 (FIGS. 19A-19B). The silicide layers 124 may comprise a silicide of the conductive fill material of the conductive features 122. For example, in some embodiments, the conductive features 122 is cobalt and the silicide layers 124 are cobalt silicide (e.g., Co₂Si, CoSi, CoSi₂, CoSi₃, or the like). In other embodiments, the silicide layers 124 comprise another silicide, such as nickel silicide. In still other embodiments, the silicide layers 124 may comprise a material such as tungsten, ruthenium, copper, combinations thereof, or the like. These are examples, and the conductive features 122 or silicide layers 124 may comprise other materials than these. In some cases, forming the silicide layers 124 may reduce the height of the conductive features 122. For example, utilizing the silicide layers 124 as described herein may obviate the need to form a separate etch stop layer over the conductive features 122.

In some embodiments, the silicide layers 124 may be formed by reacting a silicon-containing process gas with exposed conductive fill material of the conductive features 122. As an example, silicide layers 124 of cobalt silicide may be formed on conductive features 122 of cobalt using a process gas comprising silane (SiH₄), disilane (Si₂H₆), the like, or combinations thereof. In some embodiments, the process gas may have a flow rate in the range of about 1 sccm to about 1000 sccm. In some embodiments, the process gas may be mixed with a carrier gas such as H₂, He, N₂, Ar, or the like. The process gas may be flowed for a time between about 5 seconds and about 600 seconds, in some embodiments. The silicide layers 124 may be formed using a process temperature that is in the range of about 200° C. to about 600° C., in some embodiments. Other process parameters, process gases, or carrier gases are possible. In some embodiments, the silicide layers 124 may be formed having a thickness in the range of about 1 nm to about 10 nm, though other thicknesses are possible. A silicide layer 124 may have different regions with different thicknesses, in some cases. In some embodiments, the thickness of the silicide layers 124 may be controlled by controlling the flow rate and/or the flow time of the process gas.

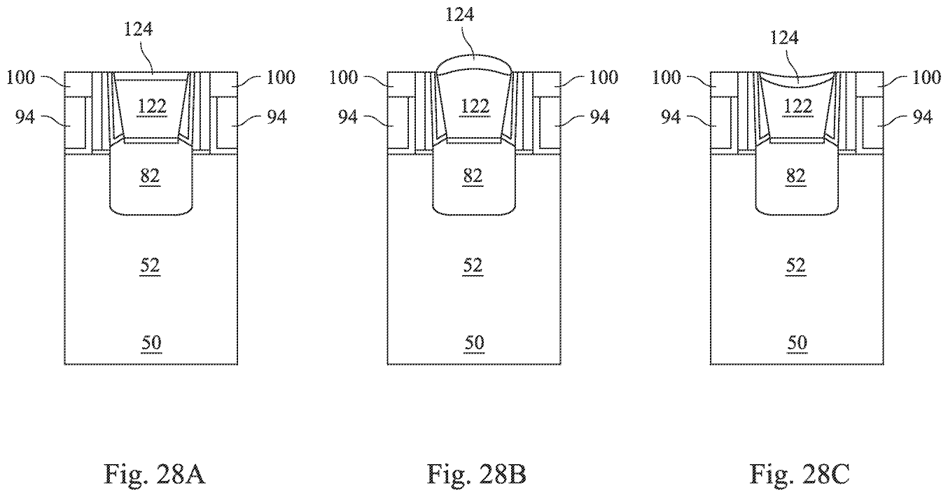

In some embodiments, the silicide layers 124 may be formed such that each silicide layers 124 covers the respective conductive feature 122. In some cases, the silicide layers 124 may extend between opposite sidewalls of the first ILD 88 and/or may extend on sidewall portions of the first ILD 88. The silicide layers 124 may have top surfaces that are concave, convex, or flat, or may have top surfaces that are above or below the top surface of the first ILD 88. Some silicide layers 124 having different top surfaces are described below for FIGS. 28A-28C.

In FIGS. 19A and 19B, a second ILD 126 is formed over the first ILD 88, the dielectric layers 100, and the silicide layers 124, in accordance with some embodiments. In some embodiments, the second ILD 126 is a flowable film formed by a flowable CVD method. In some embodiments, the second ILD 126 may be a material similar to that of the first ILD 88, and may be formed in a similar manner. For example, the second ILD 126 may be formed of a dielectric material such as an oxide, PSG, BSG, BPSG, USG, or the like, and may be deposited by any suitable method, such as CVD or PECVD.

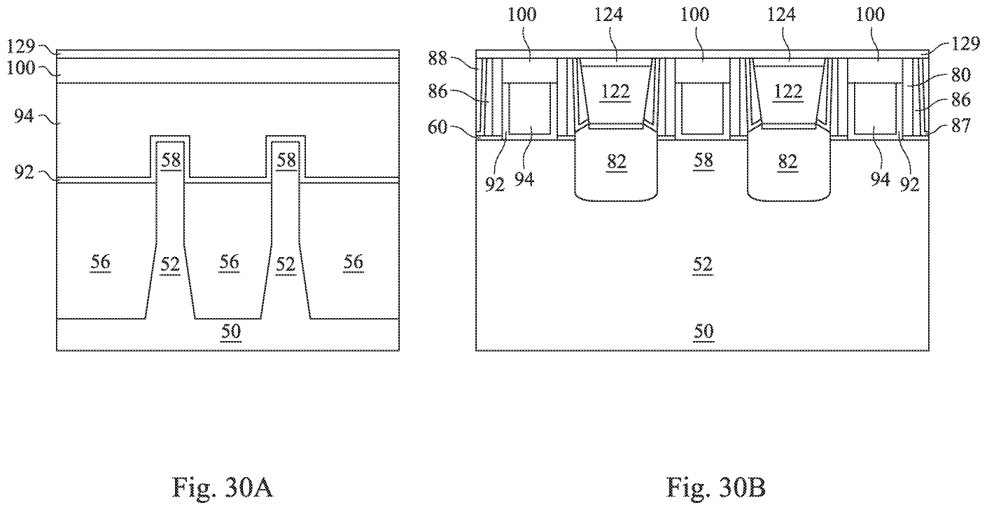

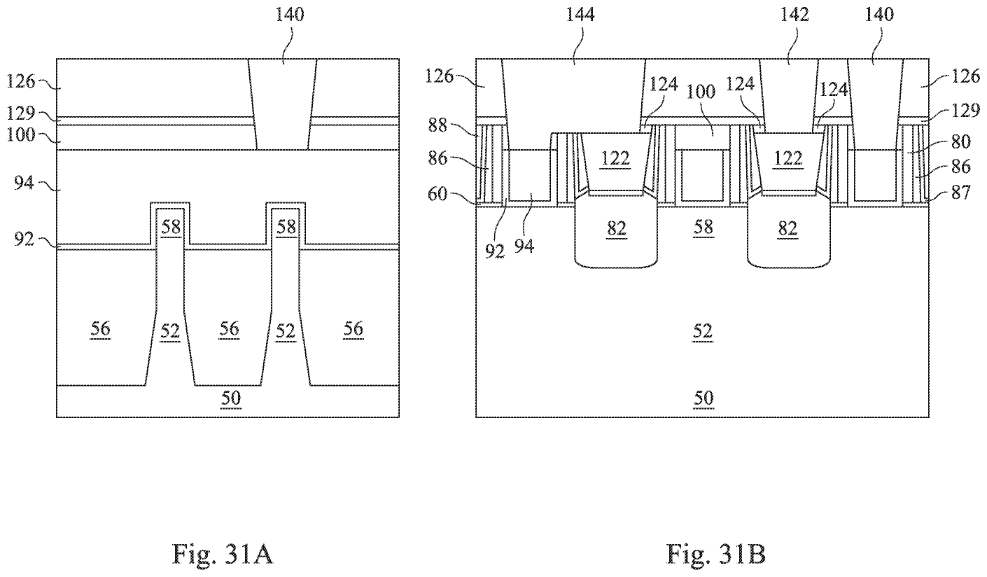

In some embodiments, the material of the silicide layers 124 and/or the material of the second ILD 126 are chosen such that the etch rate of the silicide layers 124 is less than the etch rate of the second ILD 126. In this manner, the silicide layers 124 on the conductive features 122 may be considered etch stop layers. In some cases, because the silicide layers 124 may be used as etch stop layers over the conductive features 122, the second ILD 126 may be formed over the first ILD 88, the dielectric layers 100, and the conductive features 122 without first depositing a separate etch stop layer (e.g., as a blanket layer). This is similar to the embodiment shown in FIGS. 19A-19B, in which the second ILD 126 is deposited directly on the dielectric layers 100 and the first ILD 88. Omitting the deposition of a separate etch stop layer in this manner can allow for a thinner overall device, fewer processing steps, and reduced manufacturing cost. Additionally, in some cases, the silicide layers 124 may be formed at a relatively low temperature, which can reduce the occurrence or severity of some thermal effects and can allow for the overall process to have a larger “thermal budget.” In other embodiments, a separate etch stop layer may be deposited over the first ILD 88, the dielectric layers 100, and the silicide layers 124. An embodiment in which a separate etch stop layer 129 is utilized is described below for FIGS. 30A-31B.

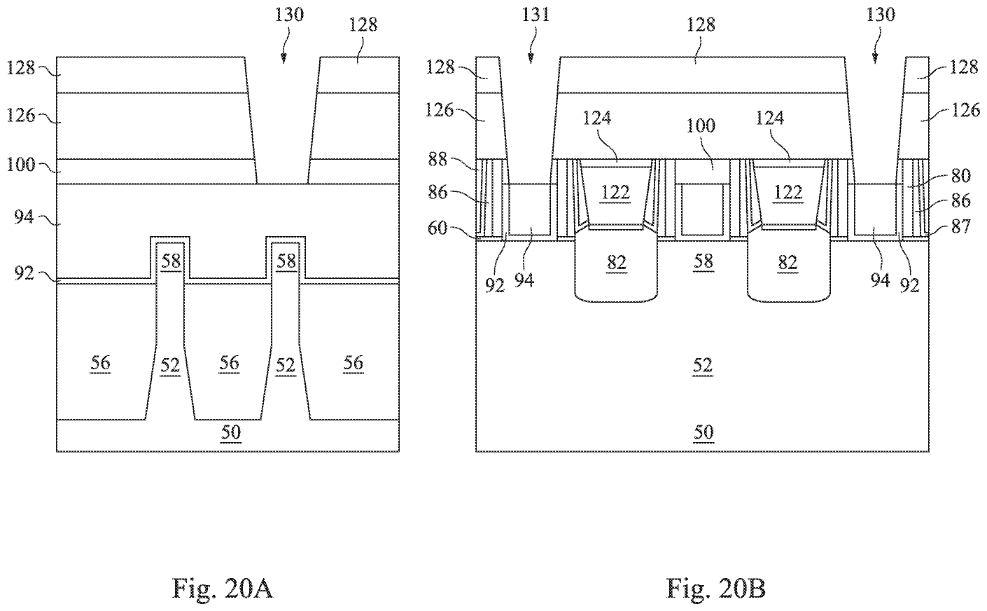

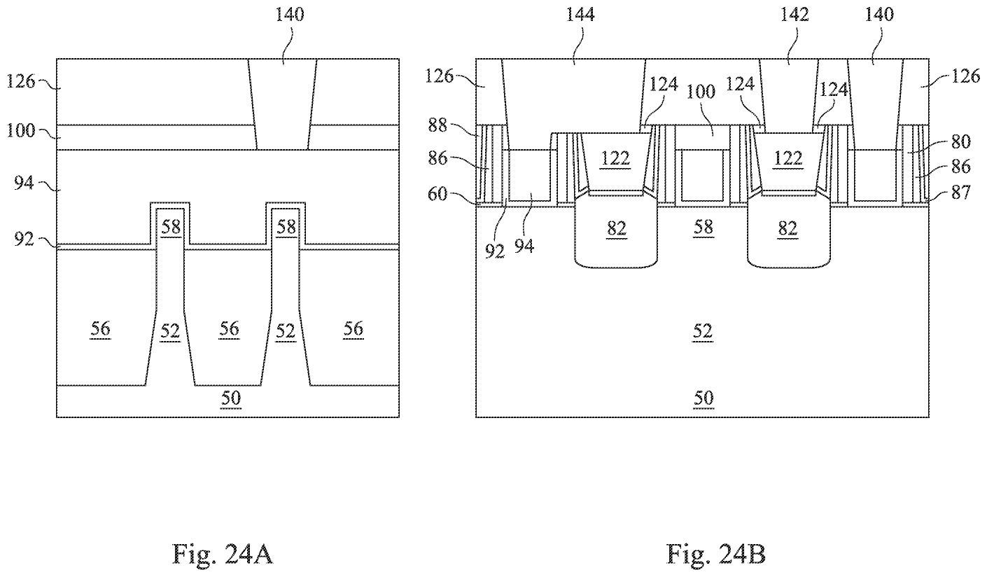

FIGS. 20A and 20B illustrate the patterning of the second ILD 126 and the dielectric layers 100 to form openings 130 and 131, in accordance with some embodiments. The openings 130 and 131 extend through the second ILD 126 and the dielectric layers 100 to expose surfaces of the gate stacks (e.g., surfaces of the gate electrodes 94). A conductive feature 140 (see FIGS. 24A-24B) is subsequently formed in the opening 130 and a portion of a combined conductive feature 144 (see FIG. 24B) is subsequently formed in the opening 131. The conductive feature 140 and the combined conductive feature 144 make physical and electrical contact to their respective gate stacks.

The second ILD 126 and the dielectric layers 100 may be patterned using acceptable photolithography and etching techniques. For example, a first photoresist 128 may be formed over the second ILD 126 and patterned using suitable photolithography techniques. The first photoresist 128 may be a single layer or multilayer photoresist structure, and may be deposited using suitable techniques such as spin-on or deposition techniques. One or more suitable etch processes may then be performed using the patterned first photoresist 128 as an etch mask, forming the openings 130 and 131. The one or more etch processes may include wet and/or dry etch processes. FIGS. 20A-20B show the openings 130 and 131 as having sloped sidewalls, but the openings 130 or 131 may have substantially vertical sidewalls, curved sidewalls, or another sidewall profile in other embodiments. The first photoresist 128 may be removed using a suitable process such as an ashing or etching process.

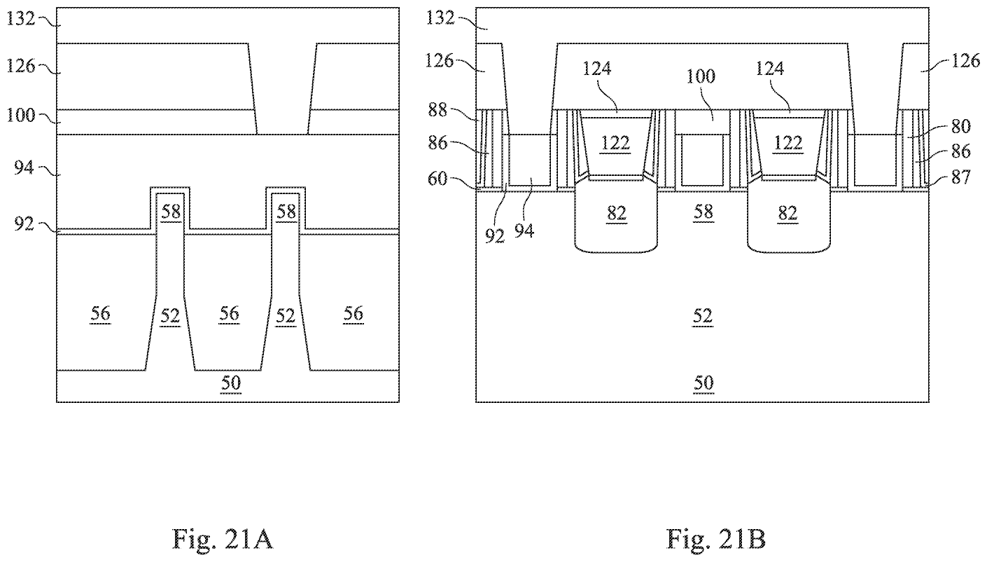

In FIGS. 21A and 21B, a second photoresist 132 is formed over the second ILD 126 and within the openings 130 and 131, in accordance with some embodiments. The second photoresist 132 may be a single layer or multilayer photoresist structure, and may be deposited using suitable techniques such as spin-on or deposition techniques. As shown in FIG. 21B, the second photoresist 132 may overfill the openings 130 and 131 and extend over the second ILD 126.

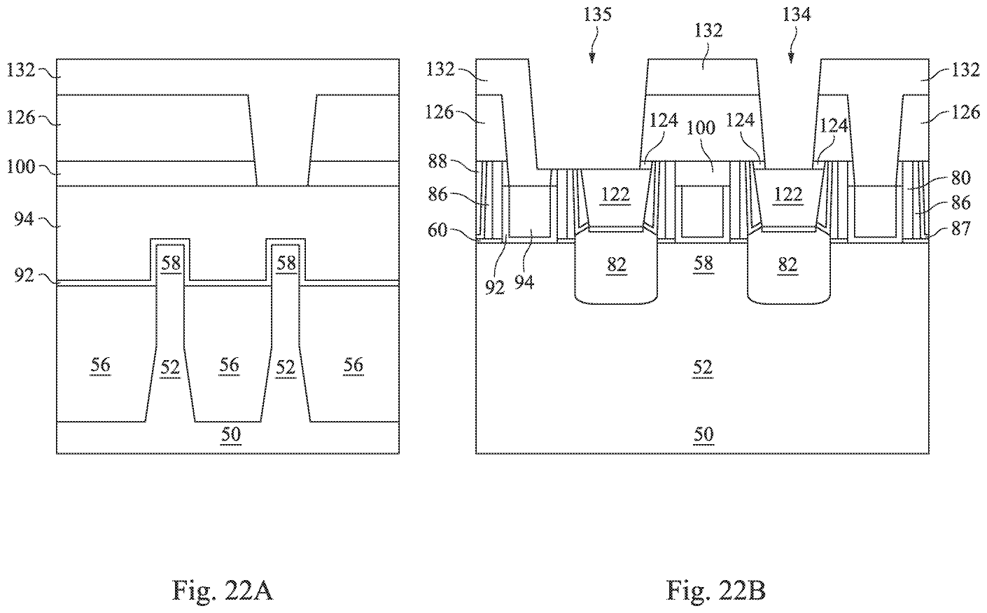

FIGS. 22A and 22B illustrate the patterning of the second photoresist 132, the second ILD 126, and the silicide layers 124 to form openings 134 and 135, in accordance with some embodiments. The openings 134 and 135 extend through the second ILD 126 and the silicide layers 124 to expose surfaces of the conductive features 122. A conductive feature 142 (see FIGS. 24A-24B) is subsequently formed in the opening 134 and a portion of the combined conductive feature 144 (see FIG. 24B) is also subsequently formed in the opening 135. The conductive feature 142 and the combined conductive feature 144 make physical and electrical contact to their respective gate stacks.

The second photoresist 132, the second ILD 126 and the silicide layers 124 may be patterned using acceptable photolithography and etching techniques. For example, the second photoresist 132 may first be formed over the second ILD 126 and patterned using suitable photolithography techniques. One or more suitable etch processes may then be performed using the patterned second photoresist 132 as an etch mask, forming the openings 134 and 135. The one or more etch processes may include wet and/or dry etch processes. The etch process(es) may remove portions of the second ILD 126 and then stop or slow at the silicide layers 124. Using the silicide layers 124 as an etch stop in this manner can reduce the chance of overetching, which can reduce the chance of forming leakage paths or other process defects. The etch process(es) may also remove portions of the silicide layers 124 to expose the conductive features 122, or a separate etching step may be performed to remove the portions of the silicide layers 124 and expose the conductive features 122. In some embodiments, this separate etching step may comprise an etching process that is different from an etching process used to etch the second ILD 126. As shown in FIG. 22B, the openings 134 or 135 may expose sidewall portions of the silicide layers 124.

In some embodiments, the etch process(es) may also remove portions of the first ILD 88, the CESL 87, the gate spacers 86, the gate seal spacers 80, the dielectric layers 100, and/or the second photoresist 132. In some embodiments, the opening 135 overlaps the previously formed opening 131. As such, the opening 135 may extend into a region of the second photoresist 132 within the previously formed opening 131, as shown in FIG. 22B. FIGS. 22A-22B show the openings 134 and 135 as having sloped sidewalls, but the openings 134 or 135 may have substantially vertical sidewalls, curved sidewalls, or another sidewall profile in other embodiments.

The one or more etch processes may be chosen such that the etch rate of the silicide layers 124 is slower than the etch rate of the second ILD 126 or other layers. For example, in some embodiments, the etch process comprises a dry etch using one or more process gases such as CF₄, CH₂F₂, CHF₃, C₄F₆, O₂, the like, or a combination thereof. The etch process may include a plasma power in the range of about 50 W to about 1000 W, a voltage bias in the range of about 0 V to about 450 V, a temperature in the range of about 20° C. to about 200° C., or a pressure in the range of about 5 mTorr to about 500 mTorr. Other process gases or process parameters are possible. In some embodiments, the etching selectivity of the second ILD 126 over the silicide layers 124 may be in the range of about 2:1 to about 4:1, though selectivities greater than about 4:1 are possible.

FIG. 22B illustrates an embodiment in which the etch process(es) remove portions of the silicide layers 124 and expose portions of the conductive features 122. In other embodiments, the etch process(es) may stop on or within the silicide layers 124, leaving the conductive features 122 covered by the silicide layers 124. In some embodiments, the subsequently formed conductive features 140, 142, or 144 (see FIGS. 24A-24B) may be formed on the silicide layers 124 covering the conductive features 122. In some embodiments, the silicide layers 124 covering the conductive features 122 may be removed using a separate etch process. For example, the silicide layers 124 may be removed by a separate dry etch process that uses using one or more process gases such as CF₄, CH₂F₂, CHF₃, C₄F₆, H₂, the like, or a combination thereof. Other etch processes are possible. In some embodiments, portions of the silicide layers 124 may be removed by a subsequently performed wet clean process, which may result in the conductive features 122 being exposed.

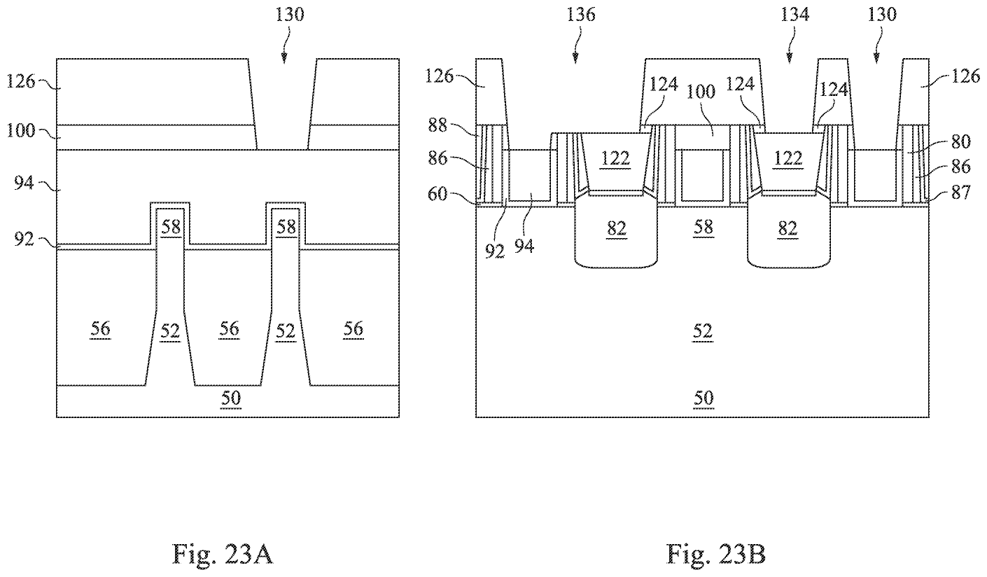

In FIGS. 23A and 23B, the second photoresist 132 is removed, forming openings 130, 134, and 136, in accordance with some embodiments. The second photoresist 132 may be removed using a suitable technique, such as by ashing, etching, or the like. As shown in FIGS. 23A-23B, removing the second photoresist 132 reveals the previously formed opening 130 that exposes a gate stack. Due to the overlap between the previously formed openings 131 and 135, removing the second photoresist 132 forms a combined opening 136 that exposes the gate stack previously exposed by the opening 131 and the conductive feature 122 previously exposed by the opening 135. The opening 134 remains exposing a conductive feature 122. In some embodiments, a wet cleaning process is performed before and/or after removing the second photoresist 132.

In FIGS. 24A and 24B, a conductive feature 140, a conductive feature 142, and a combined conductive feature 144 are formed respectively in the opening 130, the opening 134, and the combined opening 136, in accordance with some embodiments. The conductive feature 140 makes electrical connection to a gate electrode 94 of a gate stack. Accordingly, the conductive feature 140 may be referred to as a gate contact or gate contact plug in some cases. The conductive feature 142 makes electrical connection to a conductive feature 122 that is electrically connected to an epitaxial source/drain region 82. Accordingly, a combination of the conductive feature 142 and the underlying conductive feature 122 may be also referred to as a source/drain contact or a source/drain contact plug in some cases. The combined conductive feature 144 is electrically connected to both a gate stack and an epitaxial source/drain region 82 (through a conductive feature 122). In this manner, a FinFET device comprising gate contact plugs and source/drain contact plugs may be formed.

As an example of forming the conductive features 140, 142 and 144, a liner (not shown), such as a barrier layer, an adhesion layer, or the like, and a conductive material are formed in the openings 130, 134, and 136. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 126. The remaining liner and conductive material form the conductive features 140, 142 and 144. The conductive features 140, 142 and 144 may be formed in different processes or may be formed in the same process. Although shown as being formed in the same cross-sections, it should be appreciated that the conductive features 140, 142 and/or 144 may be formed in different cross-sections, which may avoid shorting.

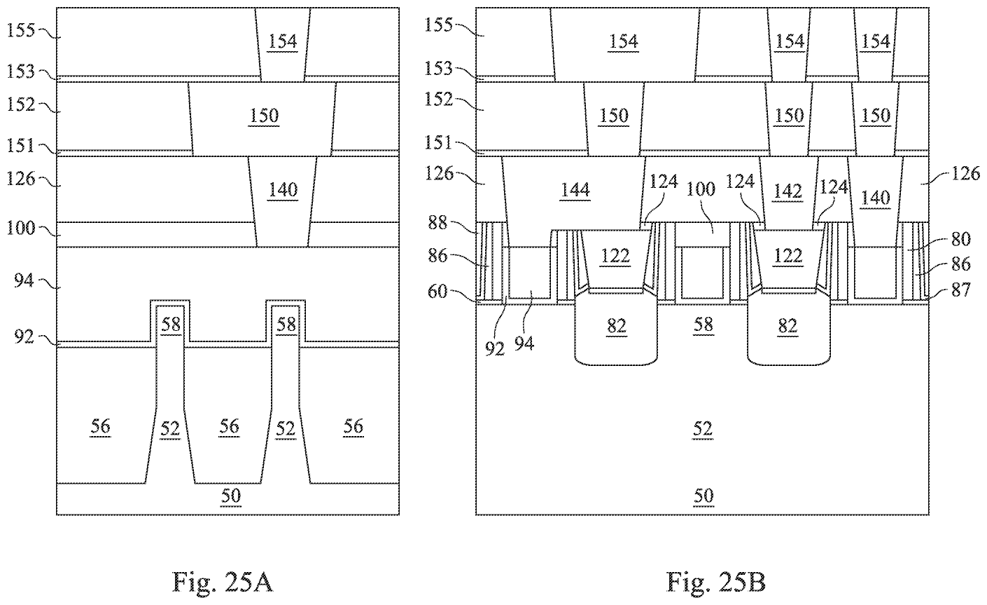

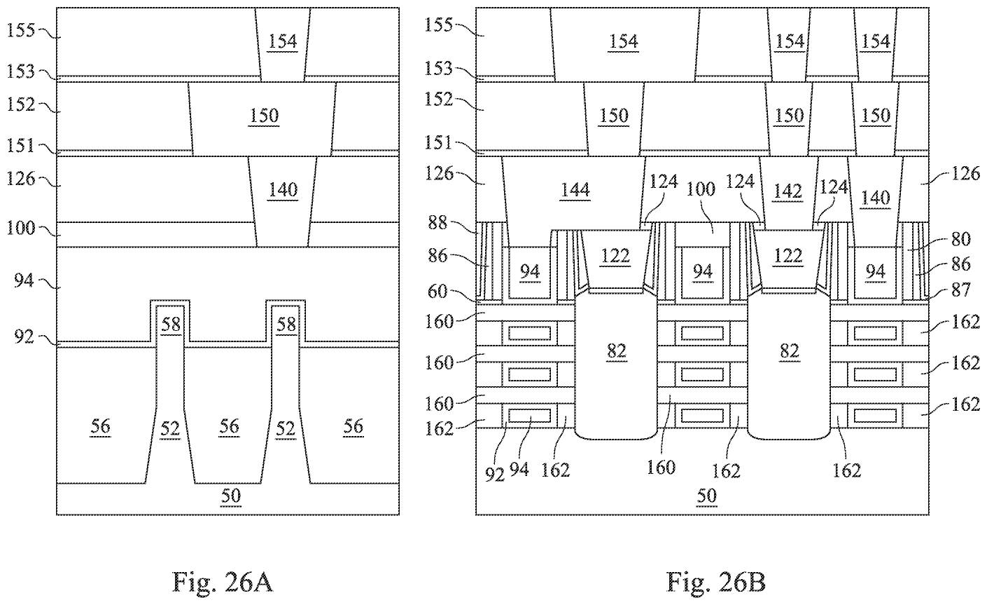

In FIGS. 25A and 25B, in some embodiments, an interconnect structure comprising one or more layers of conductive features are formed over and electrically connected to the conductive features 140, 142, and 144. In some embodiments, the interconnect structure comprises a plurality of dielectric layers such as inter-metal dielectrics (IMDs) and conductive features within the IMDs that provide various electrical interconnections. FIGS. 26A-26B illustrate an IMD 152 with conductive features 150 and an IMD 155 with conductive features 154, but more or fewer IMDs or conductive features may be formed in other embodiments. The conductive features may comprise electrical routing, conductive vias, conductive lines, or the like, and may be formed using a single damascene method, a dual damascene method, a combination thereof, or the like.

As an example of forming the IMD 152 and conductive features 150, an etch stop layer 151 may first be deposited over the second ILD 126 and conductive features 140, 142, and 144. The etch stop layer 151 may comprise a material such as silicon nitride, silicon oxynitride, aluminum oxide, aluminum nitride, the like, or combinations thereof. Other materials are possible. The IMD 152 may then be formed over the etch stop layer 151. The IMD 152 may be a material similar to that described for the first ILD 88 or the second ILD 126, and may be formed in a similar manner. In some embodiments, the IMD 152 may be formed of a low-k dielectric material having a k-value lower than about 3.5. Other materials or techniques are possible.

Openings may then be patterned in the IMD 152 and the etch stop layer 151 to expose surfaces of the conductive features 140, 142, and/or 144. An optional liner (not shown) may first be formed in the openings, which may be similar to the liner described previously for the conductive features 140, 142, and 144. A conductive material may be deposited within the openings to form the conductive features 150. The conductive material may be similar to those described for the conductive features 140, 142, and 144, and may be formed in a similar manner. Other conductive materials or techniques are possible. A planarization process may be performed to remove excess conductive material from the IMD 152. FIGS. 25A-25B show the conductive features 150 as having sloped sidewalls, but the conductive features 150 may have substantially vertical sidewalls, curved sidewalls, or another sidewall profile in other embodiments.

The conductive features 154 may be formed in a similar manner as the conductive features 150, in some embodiments. For example, an etch stop layer 153 may be formed over the IMD 152 and conductive features 150, and the IMD 155 may be formed over the IMD 152. The etch stop layer 153 and the IMD 152 may be patterned to form openings. Some of the openings may expose the conductive features 150. A liner and a conductive material may then be deposited in the openings, and a CMP process may be performed to remove excess materials. This is an example, and other techniques are possible.

The disclosed FinFET embodiments could also be applied to nanostructure devices such as nanostructure (e.g., nanosheet, nanowire, gate-all-around (GAA), or the like) field effect transistors (NFETs/NSFETs). As an example, FIGS. 26A and 26B are cross-sectional views of a nanostructure device, in accordance with some embodiments. The nanostructure device is similar to the FinFET device shown in FIGS. 25A-25B, except for the formation of active regions comprising nanostructures 160 rather than active regions comprising fins 52. Similar features in FIGS. 25A-25B and FIGS. 26A-26B may be labeled by similar numerical references, and descriptions of the similar features are not repeated herein. In an NSFET embodiment, the fins as described for the FinFET embodiment are replaced by nanostructures formed by patterning a stack of alternating layers of channel layers and sacrificial layers. Source/drain regions are formed in a manner similar to the above-described embodiments. After the dummy gate stacks are removed, the sacrificial layers can be partially or fully removed in channel regions. Replacement gate structures (e.g., gate stacks) are formed in a manner similar to the above-described embodiments. The replacement gate structures may partially or completely fill openings left by removing the sacrificial layers, and the replacement gate structures may partially or completely surround the channel layers in the channel regions of the NSFET devices.

For example, in the nanostructure device of FIGS. 26A-26B, active regions comprise a plurality of nanostructures 160 such that each nanostructure 160 is surrounded by a portion of a respective gate stack comprising gate dielectric layers 92 and gate electrodes 94. The nanostructures 160 may comprise nanosheets, nanowires, or the like. In some embodiments, the nanostructures 160 and the substrate 50 comprise a similar semiconductor material. In other embodiments, the nanostructures 160 and the substrate 50 comprise different semiconductor materials. In some embodiments, portions of the gate stacks are interposed between adjacent nanostructures 160. In some embodiments, spacers 162 are interposed between the portions of the gate stacks and the epitaxial source/drain regions 82 and act as isolation features between the gate stacks and the epitaxial source/drain regions 82. In some embodiments, the spacers 162 comprise a material such as silicon nitride or silicon oxynitride, although any suitable material, such as a low-k dielectric material, may be utilized. Conductive features contacting the replacement gate structures and the source/drain regions may be formed in a manner similar to the above-described embodiments. For example, a silicide layer 124 may be formed on the conductive features 122, which may be similar to the silicide layers 124 described previously. A nanostructure device can be formed as disclosed in U.S. Patent Application Publication No. 2016/0365414, which is incorporated herein by reference in its entirety.

FIGS. 27A, 27B, and 27C illustrate conductive features 122 having respective top surfaces that are flat, concave, and convex, in accordance with some embodiments. The conductive features 122 shown in FIGS. 27A-27C may be similar to those described for FIGS. 17A-17B. For example, FIGS. 27A-27C show conductive features 122 after a planarization process has been performed on a conductive fill material. In some embodiments, the profile of the top surfaces of the conductive features 122 may be controlled by controlling the parameters of the planarization process, such as controlling the slurry properties, the polish rate, or the like.

FIG. 27A illustrates a conductive feature 122 having a flat top surface, in accordance with some embodiments. The conductive feature 122 may have a flat top surface that is level with top surfaces of the first ILD 88 and/or the dielectric layers 100. In other embodiments, the flat top surface of the conductive feature 122 may be below top surfaces of the first ILD 88 and/or the dielectric layers 100 (not illustrated). In some cases, an anneal process performed after the planarization process may reduce the height of the conductive feature 122 such that the top surface of the conductive feature 122 may be below top surfaces of the first ILD 88 and/or the dielectric layers 100. In some embodiments, a flat top surface may be formed by controlling the planarization process, as described above.

FIG. 27B illustrates a conductive feature 122 having a convex top surface, in accordance with some embodiments. In some cases, an anneal process performed after the planarization process may cause the conductive fill material of the conductive feature 122 to reflow and form a convex top surface. In some embodiments, a convex top surface may be formed by controlling the planarization process, as described above. The convex top surface may protrude above the top surfaces of the first ILD 88 and/or the dielectric layers 100, as shown in FIG. 27B. In some cases, a conductive feature 122 having a convex top surface may allow for improved contact (e.g., less resistance) between the conductive feature 122 and an overlying conductive feature, such as conductive features 140, 142, or 144 shown in FIGS. 24A-24B. The improved contact may be due to, for example, increased contact surface area.

FIG. 27C illustrates a conductive feature 122 having a concave top surface, in accordance with some embodiments. In some cases, an anneal process performed after the planarization process may reduce the height of a conductive feature 122 such that the conductive feature 122 forms a concave top surface. In some embodiments, a concave top surface may be formed by controlling the planarization process, as described above. For example, the concave top surface may be formed from “dishing” during the planarization process. The concave top surface may be below the top surfaces of the first ILD 88 and/or the dielectric layers 100, as shown in FIG. 27C.

FIGS. 28A, 28B, and 28C show silicide layers 124 formed on the conductive features 122 of FIGS. 27A, 27B, and 27C, in accordance with some embodiments. The silicide layers 124 shown in FIGS. 28A-28C may be similar to the silicide layers 124 described previously for FIGS. 18A-18B, and may be formed using similar techniques. FIG. 28A shows a silicide layer 124 formed on the flat top surface of the conductive feature 122 of FIG. 17A, in accordance with some embodiments. The silicide layer 124 may have a substantially flat top surface or a convex top surface, which may be below, above, or about level with the top surfaces of the first ILD 88 and/or the dielectric layers 100. FIG. 28B shows a silicide layer 124 formed on the convex top surface of the conductive feature 122 of FIG. 17B, in accordance with some embodiments. The silicide layer 124 may have a convex shape, as shown in FIG. 28B. The silicide layer 124 may have a concave bottom surface. FIG. 28C shows a silicide layer 124 formed on the concave top surface of the conductive feature 122 of FIG. 17C, in accordance with some embodiments. The silicide layer 124 may have a concave top surface, a substantially flat top surface, or a convex top surface, which may be below, above, or about level with the top surfaces of the first ILD 88 and/or the dielectric layers 100. The silicide layer 124 may have a convex bottom surface. Silicide layers 124 having other shapes or profiles are possible.

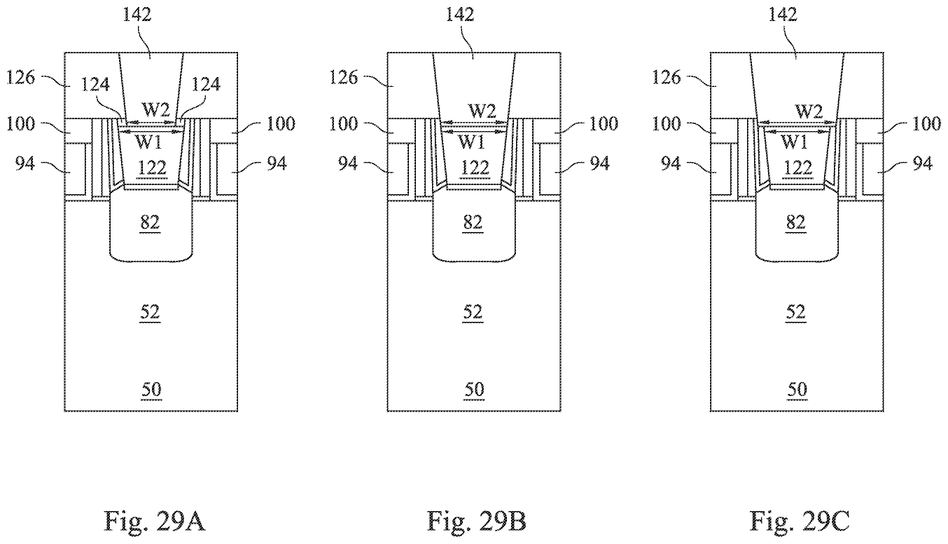

FIGS. 29A, 29B, and 29C illustrate conductive features 122 and overlying conductive features 142 having different relative widths, in accordance with some embodiments. The conductive features 122 may be similar to the conductive features 122 described previously for FIG. 18B. For example, silicide layers 124 may be formed on the conductive features 122 using techniques described herein. The conductive features 142 may be similar to the conductive features 142 described previously for FIG. 24B. In each of the FIGS. 29A-29C, the width of the top surface of the conductive feature 122 is labeled “W1” and the width of the bottom surface of the overlying conductive feature 142 is labeled “W2.”

FIG. 29A illustrates a conductive feature 142 having a width W2 that is less than the width W1 of a conductive feature 122, in accordance with some embodiments. As shown in FIG. 29A, forming a conductive feature 142 having a width W2 less than width W1 can result in portions of the silicide layer 124 remaining on the conductive feature 122 after formation of the conductive feature 142. In some cases, the conductive feature 142 may extend through the silicide layer 124, and portions of the conductive feature 142 may be covered by portions of the silicide layer 124. In some embodiments, the conductive features 142 may be at least partially surrounded by portions of the silicide layer 124. In some cases, forming a conductive feature 142 having a relatively smaller W2 can reduce the risk of via-via leakage, via bridging defects, “tiger-tooth” defects, defects resulting from photolithography overlay issues, or the like.

FIG. 29B illustrates a conductive feature 142 having a width W2 that is approximately the same as the width W1 of a conductive feature 122, in accordance with some embodiments. In some cases, forming a conductive feature 142 having a width W2 about the same as width W1 can reduce the risk of via-via leakage, via bridging defects, “tiger-tooth” defects, defects resulting from photolithography overlay issues, or the like. FIG. 29C illustrates a conductive feature 142 having a width W2 that is larger than the width W1 of a conductive feature 122, in accordance with some embodiments. In some cases, forming a conductive feature 142 having a width W2 larger than width W1 can increase the contact area between the conductive feature 122 and the conductive feature 142. Increasing the contact area in this manner can reduce contact resistance between the conductive feature 122 and the conductive feature 142 and improve device performance.

FIGS. 30A and 30B illustrate an embodiment in which an etch stop layer 129 is formed over the silicide layers 124. In some cases, the use of the silicide layers 124 can allow for a thinner etch stop layer 129 to be formed over the conductive features 122, which can reduce the overall thickness of the device. FIGS. 30A-30B illustrate a structure similar to that shown in FIGS. 18A-18B, except that an etch stop layer 129 is deposited over the silicide layers 124, the first ILD 88, the dielectric layers 100, and other exposed layers.

The etch stop layer 129 may comprise a dielectric material, such as silicon nitride, silicon oxy-nitride, silicon carbide, silicon carbo-nitride, a metal oxide, a metal nitride, the like, or a combination thereof. The etch stop layer 129 may be deposited using one or more suitable techniques, such as CVD, ALD, PVD, or the like. In some embodiments, the etch stop layer 129 may have a thickness that is in the range of about 1 nm to about 20 nm, though other thicknesses are possible. The etch stop layer 129 may be deposited as a blanket layer.

In FIGS. 31A and 31B, conductive features 140, 142, and 144 are formed on the structure shown in FIGS. 30A-30B, in accordance with some embodiments. The conductive features 140, 142, and 144 may be similar to those described previously for FIGS. 24A-24B, and may be formed using techniques similar to those described for FIGS. 19A through 24B. For example, a second ILD 126 may be formed over the etch stop layer 129 and patterned to form openings exposing gate stacks and/or conductive features 122. The second ILD 126 may be similar to the second ILD described for FIGS. 19A-19B, and the openings may be patterned using techniques similar to those described for FIGS. 20A through 23B. In some embodiments, the etch stop layer 129 is used as an etch stop when patterning the openings that expose the gate stacks and/or conductive features 122. For example, the material of the etch stop layer 129 may have a lower etch rate than the material of the overlying second ILD 126. The openings may extend through the etch stop layer 129. Conductive material may then be deposited within the openings to form the conductive features 140, 142, and 144. Other techniques for forming the conductive features 140, 142, and/or 144 are possible.

The embodiments described here have some advantages. For example, a silicide may be formed on a conductive feature to use as an etch stop instead of depositing a blanket etch stop layer over the structure. This can reduce the overall thickness of the device. Additionally, the use of a silicide as an etch stop can reduce the number of process steps, which can reduce manufacturing costs. In some cases, a silicide may be formed at a lower temperature than an etch stop layer. This can improve the overall “thermal budget” of the manufacturing process, which can improve yield, process flexibility, or device performance.

In accordance with some embodiments of the present disclosure, a method includes forming a gate structure over a substrate; forming a source/drain region adjacent the gate structure; forming a first interlayer dielectric (ILD) over the source/drain region; forming a contact plug extending through the first ILD that electrically contacts the source/drain region; forming a silicide layer on the contact plug; forming a second ILD extending over the first ILD and the silicide layer; etching an opening extending through the second ILD and the silicide layer to expose the contact plug, wherein the silicide layer is used as an etch stop during the etching of the opening; and forming a conductive feature in the opening that electrically contacts the contact plug. In an embodiment, the silicide layer includes a cobalt silicide. In an embodiment, etching the opening leaves the contact plug free of the silicide layer. In an embodiment, a top surface of the silicide layer protrudes above a top surface of the first ILD. In an embodiment, the second ILD is silicon oxide. In an embodiment, the method the silicide layer laterally surrounds the conductive feature. In an embodiment, the second ILD physically contacts the silicide layer and the first ILD. In an embodiment, the method includes forming nanostructures over the substrate, wherein the gate structure surrounds each of the nanostructures.

In accordance with some embodiments of the present disclosure, a method includes forming a fin protruding from a substrate; forming a gate stack on sidewalls of the fin and over the fin; forming a source/drain region in the fin adjacent the gate stack; forming a first conductive feature on the source/drain region, wherein the first conductive feature electrically contacts the source/drain region; forming a silicide layer on the top surface of the first conductive feature; forming an insulating layer over the gate stack and over the silicide layer, wherein the insulating layer physically contacts the silicide layer; performing a first etching process to etch an opening in the insulating layer, wherein the first etching process selectively etches the material of the insulating layer more than the material of the silicide layer; and forming a second conductive feature in the opening, wherein the second conductive feature extends through the insulating layer and the silicide layer to physically and electrically contact the first conductive feature. In an embodiment, the silicide layer is used as an etch stop for the first etching process. In an embodiment, forming the second conductive feature includes etching the silicide layer using a second etching process, wherein the second etching process is different from the first etching process. In an embodiment, forming the silicide layer includes exposing the first conductive feature to a silane gas. In an embodiment, the second conductive feature physically and electrically contacts the gate stack. In an embodiment, forming the first conductive feature includes performing a planarization process and performing an anneal process after the planarization process.

In accordance with some embodiments of the present disclosure a device includes a fin protruding from a substrate; a gate stack along sidewalls of the fin and over the fin; an epitaxial source/drain region in the fin adjacent the gate stack; a contact plug physically and electrically contacting a top surface of the epitaxial source/drain region; a silicide layer on a top surface of the contact plug; a first isolation region on a top surface of the silicide layer; and a conductive feature in the first isolation region and on the top surface of the contact plug, wherein a bottom surface of the conductive feature physically and electrically contacts the top surface of the contact plug, wherein the bottom surface of the conductive feature is below the top surface of the silicide layer. In an embodiment, the conductive feature includes cobalt and the silicide layer includes a cobalt silicide. In an embodiment, a top surface of the first isolation region and a top surface of the conductive feature are level. In an embodiment, the device includes a second isolation region surrounding the contact plug, wherein the top surface of the silicide layer is below a top surface of the second isolation region. In an embodiment, the silicide layer encircles the conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate structure over a substrate;
forming a source/drain region adjacent the gate structure;
forming a first interlayer dielectric (ILD) over the source/drain region;
forming a contact plug extending through the first ILD that electrically contacts the source/drain region;
forming a silicide layer on the contact plug;
forming a second ILD extending over the first ILD and the silicide layer;
etching an opening extending through the second ILD and the silicide layer to expose the contact plug, wherein the silicide layer is used as an etch stop during the etching of the opening; and
forming a conductive feature in the opening that electrically contacts the contact plug.

2. The method of claim 1, wherein the silicide layer comprises a cobalt silicide.

3. The method of claim 1, wherein etching the opening leaves the contact plug free of the silicide layer.

4. The method of claim 1, wherein a top surface of the silicide layer protrudes above a top surface of the first ILD.

5. The method of claim 1, wherein the second ILD is silicon oxide.

6. The method of claim 1 further comprising depositing an etch stop layer on the second ILD.

7. The method of claim 1, wherein the silicide layer laterally surrounds the conductive feature.

8. The method of claim 1, wherein the second ILD physically contacts the silicide layer and the first ILD.

9. The method of claim 1 further comprising forming a plurality of nanostructures over the substrate, wherein the gate structure surrounds each of the nanostructures of the plurality of nanostructures.

10. A method comprising:
forming a fin protruding from a substrate;
forming a gate stack on sidewalls of the fin and over the fin;
forming a source/drain region in the fin adjacent the gate stack;
forming a first conductive feature on the source/drain region, wherein the first conductive feature electrically contacts the source/drain region;
forming a silicide layer on the top surface of the first conductive feature;
forming an insulating layer over the gate stack and over the silicide layer, wherein the insulating layer physically contacts the silicide layer;
performing a first etching process to etch an opening in the insulating layer, wherein the first etching process selectively etches the material of the insulating layer more than the material of the silicide layer; and
forming a second conductive feature in the opening, wherein the second conductive feature extends through the insulating layer and the silicide layer to physically and electrically contact the first conductive feature.

11. The method of claim 10, wherein the silicide layer is used as an etch stop for the first etching process.

12. The method of claim 10, wherein forming the second conductive feature comprises etching the silicide layer using a second etching process, wherein the second etching process is different from the first etching process.

13. The method of claim 10, wherein forming the silicide layer comprises exposing the first conductive feature to a silane gas.

14. The method of claim 10, wherein the second conductive feature physically and electrically contacts the gate stack.

15. The method of claim 10, wherein forming the first conductive feature comprises performing a planarization process and performing an anneal process after the planarization process.

16. A device comprising:
a fin protruding from a substrate;
a gate stack along sidewalls of the fin and over the fin;
an epitaxial source/drain region in the fin adjacent the gate stack;
a contact plug physically and electrically contacting a top surface of the epitaxial source/drain region;
a silicide layer on a top surface of the contact plug;
a first isolation region on a top surface of the silicide layer; and
a conductive feature in the first isolation region and on the top surface of the contact plug, wherein a bottom surface of the conductive feature physically and electrically contacts the top surface of the contact plug, wherein the bottom surface of the conductive feature is below the top surface of the silicide layer.

17. The device of claim 16, wherein the conductive feature comprises cobalt and the silicide layer comprises a cobalt silicide.

18. The device of claim 16, wherein a top surface of the first isolation region and a top surface of the conductive feature are level.

19. The device of claim 16 further comprising a second isolation region surrounding the contact plug, wherein the top surface of the silicide layer is below a top surface of the second isolation region.

20. The device of claim 16, wherein the silicide layer encircles the conductive feature.
